(19) United States
(12) Patent Application Publication
(10) Pub. No.: US 2025/0036031 A1
(43) Pub. Date: Jan. 30, 2025

(54) TARGET ASYMMETRY MEASUREMENT FOR SUBSTRATE ALIGNMENT IN LITHOGRAPHY SYSTEMS

(71) Applicant: ASML Netherlands B.V., Veldhoven (NL)

(72) Inventors: Aniruddha Ramakrishna SONDE, Stamford, CT (US); Mahesh Upendra AJGAONKAR, Guilford, CT (US); Krishanu SHOME, Cheshire, CT (US); Simon Reinald HUISMAN, Eindhoven (NL); Sebastianus Adrianus GOORDEN, Eindhoven (NL); Franciscus Godefridus Casper BIJNEN, Valkenswaard (NL); Patrick WARNAAR, Tilburg (NL); Sergei SOKOLOV, Eindhoven (NL)

(73) Assignee: ASML Netherlands B.V., Veldhoven (NL)

(21) Appl. No.: 18/716,007

(22) PCT Filed: Nov. 17, 2022
(86) PCT No.: PCT/EP2022/082357

§ 371 Date: Jun. 3, 2024

Related U.S. Application Data
(60) Provisional application No. 63/286,933, filed on Dec. 7, 2021.

(51) Int. Cl. G03F 7/00; G01B 11/27

(52) U.S. Cl. CPC G03F 7/706849; G01B 11/27; G03F 7/70625; G03F 7/70633; G03F 7/706837; G03F 7/706851

(57) ABSTRACT

Some embodiments of this disclosure can improve measurement of target mark asymmetry in metrology apparatuses for improving accuracy in measurements performed in conjunction with lithographic processes. For example, a metrology system can include a projection system configured to receive a plurality of diffraction orders diffracted from a target on a substrate. The metrology system can further include a detector array and a waveguide device configured to transmit the plurality of diffraction orders between the projection system and the detector array. The detector array can be configured to detect each of the plurality of diffraction orders spatially separate from other ones of the plurality of diffraction orders.

### CROSS-REFERENCE TO RELATED APPLICATIONS

This application claims priority of U.S. Provisional Patent Application No. 63/286,933, which was filed on Dec. 7, 2021, and which is incorporated herein in its entirety by reference.

### FIELD

The present disclosure relates to metrology systems, for example, methods and systems for measuring and using target mark asymmetry in metrology systems used in conjunction with lithographic processes.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps may require different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus may use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters may include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

Production speed and throughput is of great importance in lithographic fabrication of ICs and electronic devices. It is desirable for metrology systems used in fabrication to acquire measurements quickly for increasing wafer throughput. To increase measurement speed, the amount of radiation detected by the metrology system can be increased (e.g., use a brighter source) to shorten measurement time intervals while maintaining high accuracy.

### SUMMARY

Accordingly, it is desirable to improve measurement of target mark asymmetry in metrology apparatuses for improving accuracy in measurements performed in conjunction with lithographic processes.

In some embodiments, a metrology system includes a projection system configured to receive a plurality of diffraction orders diffracted from a target on a substrate. The metrology system can further include a detector array and a waveguide device configured to transmit the plurality of diffraction orders between the projection system and the detector array. The detector array can be configured to detect each of the plurality of diffraction orders spatially separate from other ones of the plurality of diffraction orders.

In some embodiments, the detector array can be configured to individually measure an intensity of each of the plurality of diffraction orders. The detector array can also be configured to determine a distribution measurement for where each of the plurality of diffraction orders land on the detector array.

In some embodiments, the metrology system can further include a processor configured to determine a characteristic of the target and to determine a correction factor. The processor can determine the correction factor based at least on one of a difference between the measured intensities of a positive diffraction order and a negative diffraction order for at least one of the plurality of diffraction orders and a change in the distribution measurement for the at least one of the plurality of diffraction orders. The processor can further revise the determined characteristic of the target based on the determined correction factor.

In some embodiments, the difference between the measured intensities of the positive diffraction order and the negative diffraction order can be based on an asymmetry of the target. Also, the change in the distribution measurement can be based on a layer thickness variation associated with the target.

In some embodiments, the detector array is configured to determine a distribution measurement for where each of the plurality of diffraction orders land on the detector array. The metrology system further includes a processor configured to determine a change in the distribution measurement for the at least one of the plurality of diffraction order, the change in the distribution measurement being based on a layer thickness variation associated with the target.

In some embodiments, the waveguide device is arranged such that the detector array is configured to detect a far field radiation pattern of an input to the waveguide device. In some embodiments, the metrology system can further include a lens system where an output of the waveguide device is located at a focal point of the lens system and the detector array is located at a conjugate focal point of the lens system. In some embodiments, a distance between the waveguide device and the detector array is arranged such that the detector array detects at a pupil plane of the projection system. In some embodiments, the metrology system can further include a mechatronic aperture configured to block or attenuate one or more of the plurality of diffraction orders, where the detector array includes a single pixel detector.

In some embodiments, the metrology system can further include a first lens system positioned at an upstream of the waveguide device, an optical element positioned at an upstream of the first lens system, and a second lens system positioned at an upstream of the optical element. In some embodiments, the detector array can include a first detector configured to detect a first one of the plurality of diffraction orders and a second detector configured to detect a second one of the plurality of diffraction orders. In some embodiments, the optical element can include at least one of a tunable order splitter, a tunable order blocker, or a spatial light modulator.

In some embodiments, the waveguide device can include a multimode fiber. In some embodiments, the waveguide device can include a fiber bundle.

In some embodiments, the waveguide device includes one or more waveguide devices, each of the one or more waveguide device arranged such that the detector array detects a different part of a pupil plane of the projection system using the corresponding one of the one or more waveguide devices.

In some embodiments, the target includes dual pitch marks including a first segment having a first pitch and a second segment having a second pitch different from the first pitch. The detector array can be further configured to detect each of the plurality of diffraction orders spatially separate from other ones of the plurality of diffraction orders in the first direction separate from the second direction.

In some embodiments, a metrology system can include a detector array and one or more waveguide devices. The one or more waveguide device can be configured to receive a plurality of diffraction orders diffracted from a target on a substrate and to transmit the plurality of diffraction orders to the detector array. The one or more waveguide devices can be arranged such that detector array detects a far field radiation pattern of an input to the one or more waveguide devices in order to detect each of the plurality of diffraction orders spatially separate from other ones of the plurality of diffraction orders.

In some embodiments, a method includes determining a characteristic of a target on a substrate and determining a difference between measured intensities of a positive diffraction order and a negative diffraction order for at least one of a plurality of diffraction orders. The plurality of diffraction orders can be diffracted from the target. The difference between the measured intensities of the positive diffraction order and the negative diffraction order can be based on an asymmetry of the target. The method further includes determining a change in a distribution measurement for the at least one of the plurality of diffraction orders. The change in the distribution measurement can be based on a layer thickness variation associated with the target. The method can further include determining a correction factor based at least on the difference between the measured intensities and the change in the distribution measurement. The method can also include revising the determined characteristic of the target based on the determined correction factor.

In some embodiments, a metrology system includes a projection system configured to receive a plurality of diffraction orders diffracted from a target on a substrate. The target can include a first grating in a first direction and a second grating in a second direction. The plurality of diffraction orders can include a first diffraction order from the first grating and a second diffraction order from the second grating. The metrology system can further include a detector array and a waveguide device configured to transmit the plurality of diffraction orders between the projection system and the detector array. The detector array can be configured to detect the first diffraction order spatially separate from the second diffraction order.

In some embodiments, the metrology system can further include a lens located at a pupil plane of the projection system.

In some embodiments, a metrology system includes a projection system configured to receive a plurality of diffraction orders diffracted from a target on a substrate. The metrology system can further include a detector and a waveguide device configured to transmit the plurality of diffraction orders between the projection system and the detector. The metrology system can further include a chopper wheel configured to rotate around a center of the chopper wheel such that the detector is configured to detect each of the plurality of diffraction orders at a frequency different from frequencies of other ones of the plurality of diffraction orders.

In some embodiments, the chopper wheel is located between the waveguide device and the detector. In some embodiments, the metrology system can further include a first high pass filter configured to filter the plurality of diffraction orders to a first set of diffraction orders having a first wavelength band and a second set of diffraction orders having a second wavelength band. The chopper wheel is located in a path of the first set of diffraction orders. The metrology system can further include a second chopper wheel located in a path of the second set of diffraction orders and a second high pass filter configured to combine the first set of diffraction orders and the second set of diffraction orders before the detector.

In some embodiments, the plurality of diffraction orders include positive diffraction orders and the chopper wheel is located in a path of the positive diffraction orders. The metrology system can further include a high pass filter configured to combine the positive diffraction orders and the negative diffraction orders after the chopper wheel and the second chopper wheel and before the detector.

In some embodiments, the chopper wheel can include a first set of openings corresponding to a first diffraction order of the plurality of diffraction orders and a second set of opening corresponding to a higher diffraction order of the plurality of diffraction orders.

In some embodiments, the chopper wheel is located before the waveguide device and the detector. The plurality of diffraction orders can include positive diffraction orders and the chopper wheel is located in a path of the positive diffraction orders. The metrology system can further include a second chopper wheel located before a second waveguide device and a second detector and in a path of negative diffraction orders.

In some embodiments, the chopper wheel includes a first ring including a first set of openings corresponding to a first diffraction order of the plurality of diffraction orders and a second ring including a second set of opening corresponding to a higher diffraction order of the plurality of diffraction orders.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a schematic of a reflective lithographic apparatus, according to some embodiments of the disclosure.

FIG. 1B shows a schematic of a transmissive lithographic apparatus, according to some embodiments of the disclosure.

FIG. 2 shows a more detailed schematic of the reflective lithographic apparatus, according to some embodiments of the disclosure.

FIG. 3 shows a schematic of a lithographic cell, according to some embodiments of the disclosure.

FIGS. 4A and 4B show schematics of inspection apparatuses, according to some embodiments of the disclosure.

FIG. 5A shows a schematic of an intensity channel of an inspection apparatus, according to some embodiments of the disclosure.

FIG. 5B shows one exemplary design for separating and individually measuring an intensity of each of a plurality of diffraction order, according to some embodiments of the disclosure.

FIG. 5C shows one exemplary energy distribution of intensity measurement on a detector, according to some embodiments of the disclosure.

FIGS. 5D and 5E show another exemplary design for separating and individually measuring an intensity of each of a plurality of diffraction order, according to some embodiments of the disclosure.

FIG. 5F shows an exemplary slideable higher order attenuation plate, according to some embodiments of the disclosure.

FIGS. 5G and 5H show exemplary pupil dividers, according to some embodiments of the disclosure.

FIG. 6 illustrates an example method 600 for determining a correction factor, according to some embodiments of the disclosure.

FIGS. 7A and 7B illustrate exemplary targets with different pitches, according to some embodiments.

FIGS. 8A and 8B illustrate exemplary targets including overlay-alignment marks, according to some embodiments.

FIG. 9 shows a schematic of an inspection apparatus configured to separate intensity measurement for a grating in a first direction from intensity measurement for a grating in a second direction, according to some embodiments.

FIG. 10A shows an exemplary design for separating and individually measuring an intensity of each of a plurality of diffraction order using chopper wheels, according to some embodiments.

FIG. 10B shows another exemplary design for separating and individually measuring an intensity of each of a plurality of diffraction order using chopper wheels, according to some embodiments.

FIG. 10C illustrates an exemplary design of a chopper wheel, according to some embodiments.

FIGS. 10D and 10E illustrate an exemplary intensity signal detected in the time domain and frequency domain, respectively, according to some embodiments.

FIG. 11A shows another exemplary design for separating and individually measuring an intensity of each of a plurality of diffraction order using chopper wheels within an optical system, according to some embodiments.

FIG. 11B illustrates an exemplary design of a chopper wheel to be used within the optical system, according to some embodiments.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment.” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below.” “lower,” “above.” “on.” “upper” or the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure can be implemented.

### Example Lithographic Systems

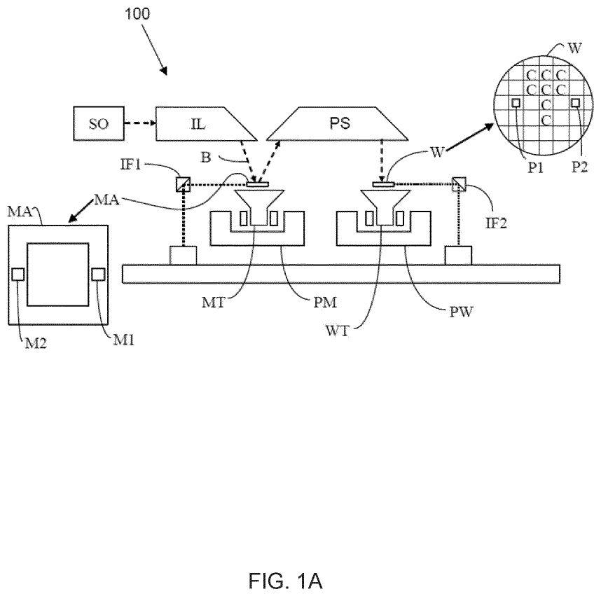

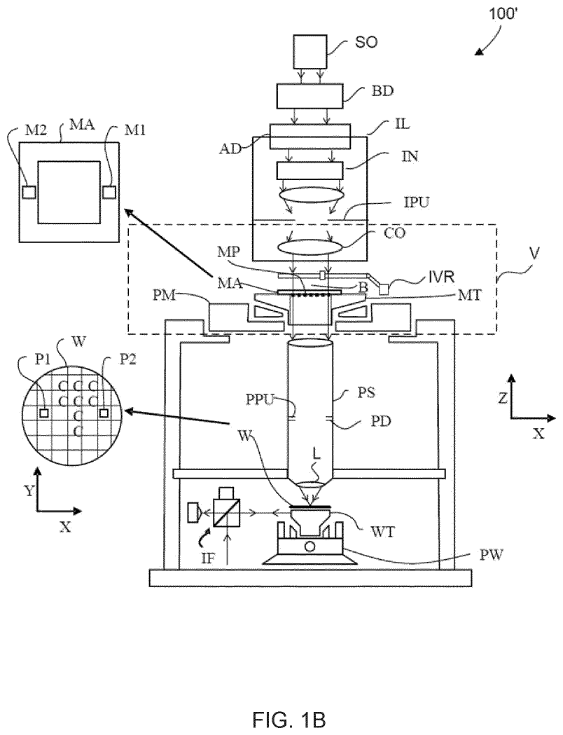

FIGS. 1A and 1B show schematic illustrations of a lithographic apparatus 100 and lithographic apparatus 100′, respectively, in which embodiments of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The terms “inspection apparatus,” “metrology apparatus,” or the like can be used herein to refer to, e.g., a device or system used for measuring a property of a structure (e.g., overlay error, critical dimension parameters) or used in a lithographic apparatus to inspect an alignment of a wafer (e.g., alignment apparatus).

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for extreme ultraviolet (EUV) or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. The source SO and the illuminator IL, together with the beam delivery system BD, if required, can be referred to as a radiation system.

The illuminator IL can include an adjuster AD (in FIG. 1B) for adjusting the angular intensity distribution of the radiation beam. Generally, at least the outer and/or inner radial extent (commonly referred to as “o-outer” and “o-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration can be reduced by providing radiation poles (not shown) in opposite quadrants of the illumination system pupil IPU. Further, in some embodiments, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IF (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator only or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ can be used in at least one of the following modes:

1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.

2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-) magnification and image reversal characteristics of the projection system PS.

3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

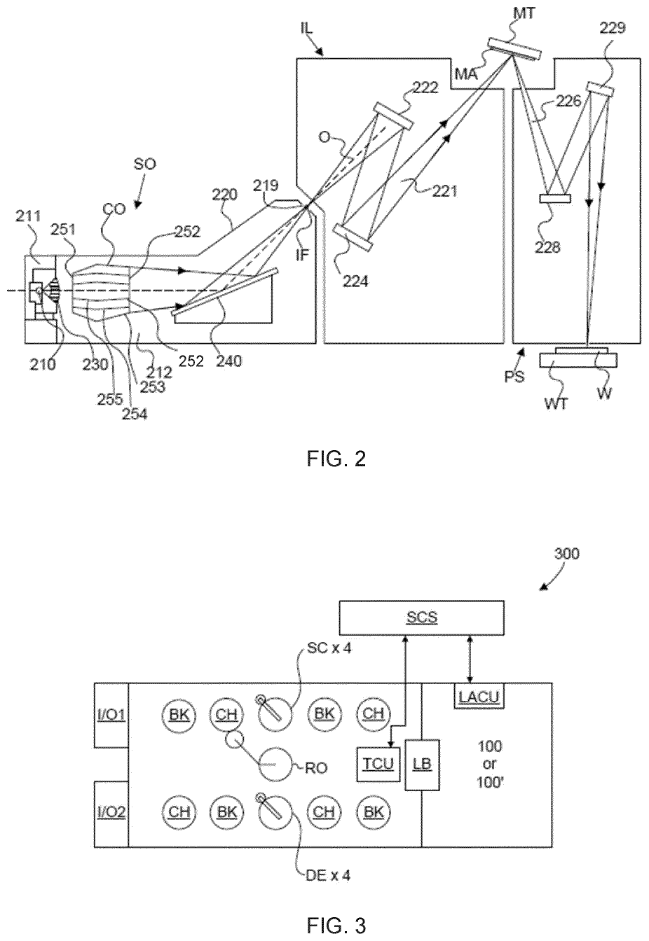

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 can be formed by a discharge produced plasma source. EUV radiation can be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor can be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which can be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF. The virtual source point IF is commonly referred to as the intermediate focus, and the source collector apparatus is arranged such that the intermediate focus IF is located at or near an opening 219 in the enclosing structure 220. The virtual source point IF is an image of the radiation emitting plasma 210. Grating spectral filter 240 is used in particular for suppressing infra-red (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination optics unit IL and projection system PS. The grating spectral filter 240 can optionally be present, depending upon the type of lithographic apparatus. Further, there can be more mirrors present than those shown in the FIG. 2, for example there can be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Exemplary Lithographic Cell

FIG. 3 shows a lithographic cell 300, also sometimes referred to a lithocell or cluster, according to some embodiments. Lithographic apparatus 100 or 100′ can form part of lithographic cell 300. Lithographic cell 300 can also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Exemplary Metrology System

In order to control the lithographic process to place device features accurately on the substrate, alignment marks are generally provided on the substrate, and the lithographic apparatus includes one or more for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement can be performed using the techniques described in U.S. Publication No. 2009/195768 A (Bijnen et al.), however. The full contents of both of these disclosures are incorporated herein by reference.

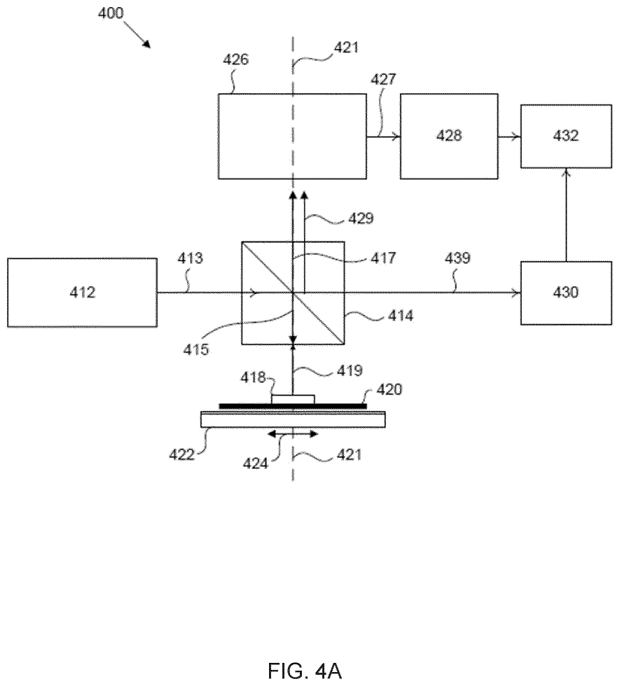

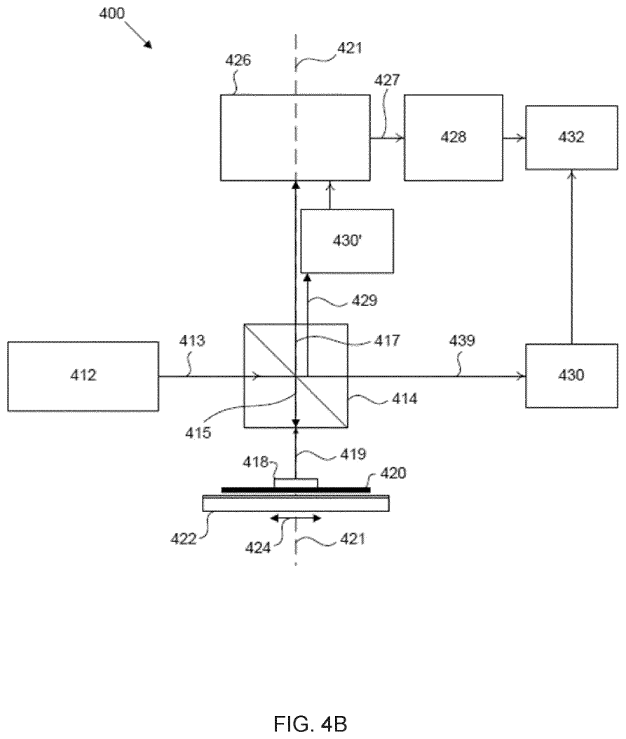

FIG. 4A shows a schematic of a cross-sectional view of a metrology system 400 that can be implemented as a part of lithographic apparatus 100 or 100′, according to some embodiments. In some embodiments, metrology system 400 can be configured to align a substrate (e.g., substrate W) with respect to a patterning device (e.g., patterning device MA). Metrology system 400 can be further configured to detect positions of alignment marks on the substrate and to align the substrate with respect to the patterning device or other components of lithographic apparatus 100 or 100′ using the detected positions of the alignment marks. Such alignment of the substrate can ensure accurate exposure of one or more patterns on the substrate.

In some embodiments, metrology system 400 can include an illumination system 412, a beam splitter 414, an interferometer 426, a detector 428, a beam analyzer 430, and an overlay calculation processor 432. Illumination system 412 can be configured to provide an electromagnetic narrow band radiation beam 413 having one or more passbands. In an example, the one or more passbands can be within a spectrum of wavelengths between about 500 nm to about 900 nm. In another example, the one or more passbands can be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values can improve long-term stability and accuracy of alignment systems (e.g., metrology system 400) compared to the current alignment apparatuses.

In some embodiments, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some embodiments, alignment mark or target 418 can have one hundred and eighty degrees (i.e., 180°) symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be (a) a resist layer grating comprising bars that are formed of solid resist lines, or (b) a product layer grating, or (c) a composite grating stack in an overlay target structure comprising a resist grating overlaid or interleaved on a product layer grating. The bars can alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, can be input to the reconstruction process, performed by processing unit PU, from knowledge of the printing step and/or other scatterometry processes.

In some embodiments, beam splitter 414 can be further configured to receive diffraction radiation beam 419 and split diffraction radiation beam 419 into at least two radiation sub-beams, according to an embodiment. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. It would be apparent to a person skilled in the relevant art that other optical arrangements can be used to obtain the similar result of illuminating alignment mark or target 418 on substrate 420 and detecting an image of alignment mark or target 418.

As illustrated in FIG. 4A, interferometer 426 can be configured to receive radiation sub-beam 417 and diffracted radiation sub-beam 429 through beam splitter 414. In an example embodiment, diffracted radiation sub-beam 429 can be at least a portion of radiation sub-beam 415 that can be reflected from alignment mark or target 418. In an example of this embodiment, interferometer 426 comprises any appropriate set of optical-elements, for example, a combination of prisms that can be configured to form two images of alignment mark or target 418 based on the received diffracted radiation sub-beam 429. It should be appreciated that a good quality image need not be formed, but that the features of alignment mark 418 should be resolved. Interferometer 426 can be further configured to rotate one of the two images with respect to the other of the two images 180° and recombine the rotated and unrotated images interferometrically.

In some embodiments, detector 428 can be configured to receive the recombined image via interferometer signal 427 and detect interference as a result of the recombined image when alignment axis 421 of metrology system 400 passes through a center of symmetry (not shown) of alignment mark or target 418. Such interference can be due to alignment mark or target 418 being 180° symmetrical, and the recombined image interfering constructively or destructively, according to an example embodiment. Based on the detected interference, detector 428 can be further configured to determine a position of the center of symmetry of alignment mark or target 418 and consequently, detect a position of substrate 420. According to an example, alignment axis 421 can be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further embodiment, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data can for example be obtained with any type of alignment sensor, for example a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some embodiments, beam analyzer 430 can be configured to receive and determine an optical state of diffracted radiation sub-beam 439. The optical state can be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of substrate 420, can be accurately known with reference to stage 422. Alternatively, beam analyzer 430 can be configured to determine a position of metrology system 400 or any other reference element, such that the center of symmetry of alignment mark or target 418 can be known with reference to metrology system 400 or any other reference element. Beam analyzer 430 can be a point or an imaging polarimeter with some form of wavelength-band selectivity. In some embodiments, beam analyzer 430 can be directly integrated into metrology system 400, or connected via fiber optics of several types: polarization preserving single mode, multimode, or imaging, according to other embodiments.

In some embodiments, beam analyzer 430 can be further configured to determine the overlay data between two patterns on substrate 420. One of these patterns can be a reference pattern on a reference layer. The other pattern can be an exposed pattern on an exposed layer. The reference layer can be an etched layer already present on substrate 420. The reference layer can be generated by a reference pattern exposed on the substrate by lithographic apparatus 100 and/or 100′. The exposed layer can be a resist layer exposed adjacent to the reference layer. The exposed layer can be generated by an exposure pattern exposed on substrate 420 by lithographic apparatus 100 or 100′. The exposed pattern on substrate 420 can correspond to a movement of substrate 420 by stage 422. In some embodiments, the measured overlay data can also indicate an offset between the reference pattern and the exposure pattern. The measured overlay data can be used as calibration data to calibrate the exposure pattern exposed by lithographic apparatus 100 or 100′, such that after the calibration, the offset between the exposed layer and the reference layer can be minimized.

In some embodiments, beam analyzer 430 can be further configured to determine a model of the product stack profile of substrate 420, and can be configured to measure overlay, critical dimension, and focus of target 418 in a single measurement. The product stack profile contains information on the stacked product such as alignment mark, target 418, or substrate 420, and can include mark process variation-induced optical signature metrology that is a function of illumination variation. The product stack profile can also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 can be further configured to process information related to a particular property of an exposed pattern in that layer. For example, beam analyzer 430 can process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some embodiments, an array of detectors (not shown) can be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range. In some embodiments, each PIN detector can have a separate pre-amp, such that the number of elements is therefore limited. In some embodiments, CCD linear arrays offer many elements that can be read-out at high speed and are especially of interest if phase-stepping detection is used.

In some embodiments, a second beam analyzer 430′ can be configured to receive and determine an optical state of diffracted radiation sub-beam 429, as shown in FIG. 4B. The optical state can be a measure of beam wavelength, polarization, or beam profile. Second beam analyzer 430′ can be identical to beam analyzer 430. Alternatively, second beam analyzer 430′ can be configured to perform at least all the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ can also be configured to determine a position of metrology system 400, or any other reference element, such that the center of symmetry of alignment mark or target 418 can be known with reference to metrology system 400, or any other reference element. Second beam analyzer 430′ can be further configured to determine the overlay data between two patterns and a model of the product stack profile of substrate 420. Second beam analyzer 430′ can also be configured to measure overlay, critical dimension, and focus of target 418 in a single measurement.

In some embodiments, second beam analyzer 430′ can be directly integrated into metrology system 400, or it can be connected via fiber optics of several types: polarization preserving single mode, multimode, or imaging, according to other embodiments. Alternatively, second beam analyzer 430′ and beam analyzer 430 can be combined to form a single analyzer (not shown) configured to receive and determine the optical states of both diffracted radiation sub-beams 429 and 439.

In some embodiments, processor 432 receives information from detector 428 and beam analyzer 430. For example, processor 432 can be an overlay calculation processor. The information can comprise a model of the product stack profile constructed by beam analyzer 430. Alternatively, processor 432 can construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 can create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 can utilize the basic correction algorithm to characterize the metrology system 400 with reference to wafer marks and/or alignment marks 418.

In some embodiments, processor 432 can be further configured to determine printed pattern position offset error with respect to the sensor estimate for each mark based on the information received from detector 428 and beam analyzer 430. The information includes, but is not limited to, the product stack profile, measurements of overlay, critical dimension, and focus of each alignment marks or target 418 on substrate 420. Processor 432 can utilize a clustering algorithm to group the marks into sets of similar constant offset error, and create an alignment error offset correction table based on the information. The clustering algorithm can be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error can be deduced. Table 1 illustrates how this can be performed. The smallest measured overlay in the example shown is −1 nm. However this is in relation to a target with a programmed overlay of-30 nm. The process may have introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value can be taken to be the reference point and, relative to this, the offset can be calculated between measured overlay and that expected due to the programmed overlay. This offset determines the overlay error for each mark or the sets of marks with similar offsets. Therefore, in the Table 1 example, the smallest measured overlay was −1 nm, at the target position with programmed overlay of 30 nm. The difference between the expected and measured overlay at the other targets is compared to this reference. A table such as Table 1 can also be obtained from marks and target 418 under different illumination settings, the illumination setting, which results in the smallest overlay error, and its corresponding calibration factor, can be determined and selected. Following this, processor 432 can group marks into sets of similar overlay error. The criteria for grouping marks can be adjusted based on different process controls, for example, different error tolerances for different processes.

In some embodiments, processor 432 can confirm that all or most members of the group have similar offset errors, and apply an individual offset correction from the clustering algorithm to each mark, based on its additional optical stack metrology. Processor 432 can determine corrections for each mark and feed the corrections back to lithographic apparatus 100 or 100′ for correcting errors in the overlay, for example, by feeding corrections into the metrology system 400.

### Exemplary Apparatuses for Target Asymmetry Measurement

According to some embodiments, interferometer 426 and detector 428 can include (or be part of) one or more phase channels of metrology system 400 of FIGS. 4A and 4B that can be configured to determine alignment and/or a position of alignment mark or target 418. In some embodiments, beam analyzer 430 and/or beam analyzer 430′ can include (or be part of) one or more intensity channels of metrology system 400 of FIGS. 4A and 4B.

As discussed in more detail below, the intensity channels of metrology system 400 of FIGS. 4A and 4B can be designed such that different diffraction orders diffracted from alignment mark or target 418 are separated at, for example, beam analyzer 430 and/or beam analyzer 430′. In other words, instead of (or in addition to) measuring a total intensity (e.g., I₊ₜₒₜₐₗ=I₊₁+I₊₂+I₊₃+ . . . ), the intensity channel can measure the intensity of different diffraction orders separately (e.g., I₊₁ and I₋₁, I₊₂ and I₋₂, etc.) Here, I is the measured intensity. According to some embodiments, by separating the diffraction orders and separately detecting the diffraction orders, metrology system 400 can be configured to measure and determine, for example, intensity imbalance (e.g., difference in intensities) for different diffraction orders.

According to some embodiments, the intensity imbalance of the diffraction orders can be due to asymmetry in alignment mark or target 418. Additionally, or alternatively, the background of alignment mark or target 418 may also contribute to the intensity imbalance of the diffraction orders.

In some embodiments, as discussed in more detail below, by determining and measuring the intensity imbalance of the diffraction orders, metrology system 400 can determine a correction factor that can be used to correct the characteristic of alignment mark or target 418 (e.g., alignment, position, overlay error, etc.) that is determined by metrology system 400.

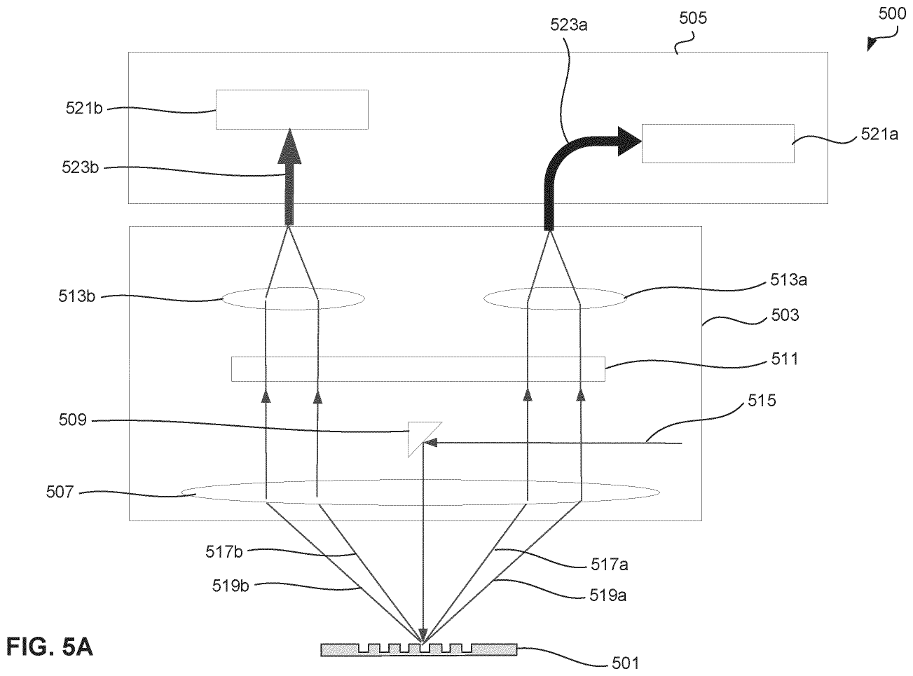

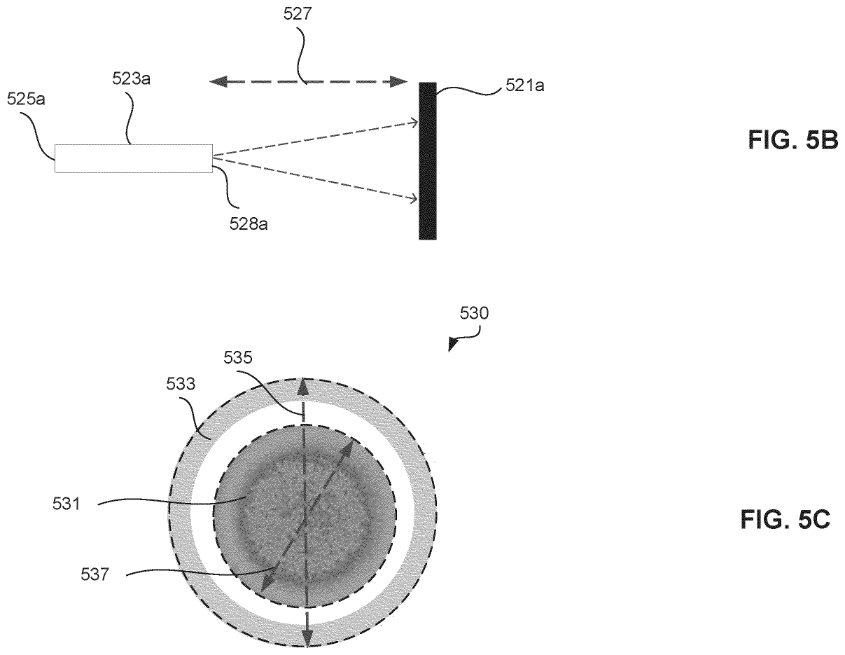

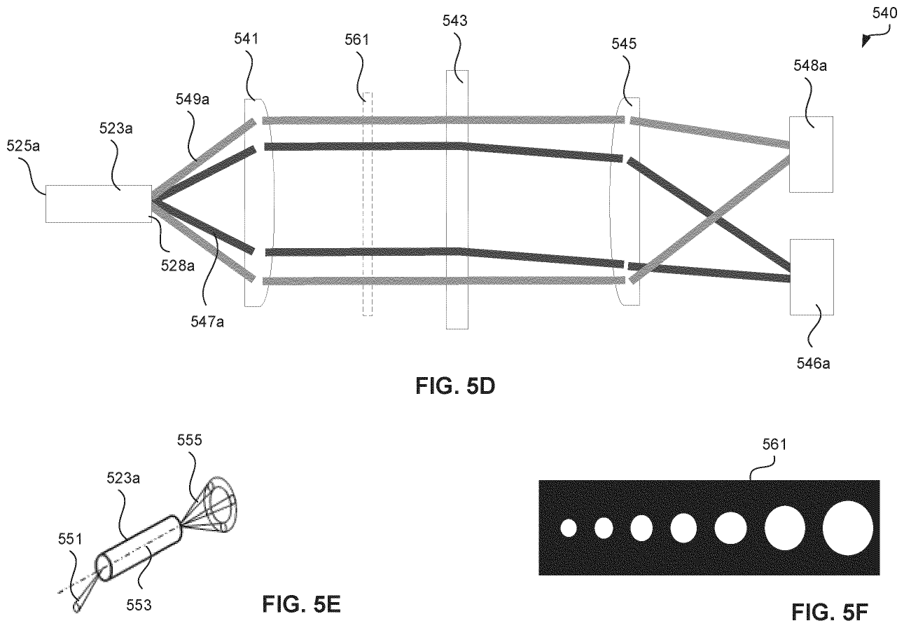

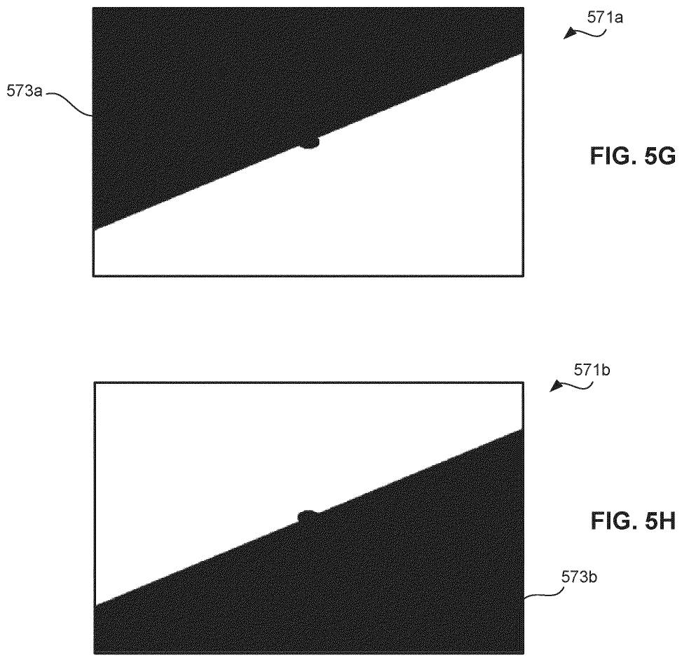

FIG. 5A shows a schematic of an intensity channel of an inspection apparatus, according to some embodiments. Intensity channel 500 can be part of metrology system 400 of FIGS. 4A and 4B, as discussed above, according to some embodiments.

As illustrated in FIG. 5A, intensity channel 500 can include target 501, optical system 503, and detection system 505. In some embodiments, target 501 can be alignment mark or target 418 of FIGS. 4A and 4B. Optical system 503 can be configured to generate (or receive from a radiation source) radiation beam 515 to irradiate target 501. Optical system 503 can also be configured to collect diffraction orders diffracted from target 501 and guide the diffraction orders to detection system 505. According to some embodiments, optical system 503 includes one or more optical devices. For example, optical system 503 can include optical element 509 configured to receive radiation beam 515 and change direction of radiation beam 515 to irradiate target 501. In some non-limiting examples, optical element 509 can include a mirror, a prism, a beam splitter, and the like.

Optical system 503 can also include projection system 507. Projection system 507 can include a lens or a system of lenses, according to some embodiments. Projection system 507 can be configured to project radiation beam 515 to target 501 and collect diffraction orders diffracted from target 501. FIG. 5A illustrates +1 diffracted radiation beam 517a, −1 diffracted radiation beam 517b, +3 diffracted radiation beam 519a, and −3 diffracted radiation beam 519b. Although four diffracted radiation beams are illustrated, the embodiments of this disclosure can include any number of diffraction orders.

According to some embodiments, optical system 503 can also include pupil divider 511. Pupil divider 511 can be configured to separate positive (+) and negative (−) diffraction order channels. For example, a positive channel branch can include a channel including diffraction orders 517a and 519a. In this example, a negative channel branch can include a channel including diffraction orders 517b and 519b. FIGS. 5G and 5H illustrate exemplary pupil dividers 571a and 571b, according to some embodiments. Pupil divider 571a of FIG. 5G can include region 573a configured to block the undesired diffraction orders in, for example, the positive (+) diffraction order channel. Pupil divider 571b of FIG. 5H can include region 573b configured to block the undesired diffraction orders in, for example, the negative (−) diffraction order channel.

Optical system 503 can also include optical elements 513a and 513b (referred herein as optical elements 513) configured to guide the diffraction orders 517 and 519 to detection system 505. According to some embodiments, optical element 513a and optical element 513b can include a lens or a system of lens.

According to some embodiments, detection system 505 can include one or more waveguide devices 523a and 523b and one or more detectors 521a and 521b. According to some embodiments, detectors 521a and 521b can be used as (or be part of) beam analyzers 430 and/or 430′ of FIGS. 4A and 4B. In some embodiments, waveguide devices 523a and 523b (herein referred to as waveguide device(s) 523) can include a multimode waveguide device. Alternatively, waveguide devices 523 can include a bundle of a plurality of single-mode waveguide devices. For example, waveguide devices 523 can include a fiber bundle (e.g., a plurality of small fibers close to each other instead of a single large-core multimode fiber). In some examples, a single-mode waveguide device can include a single-mode fiber. In some examples, a multimode waveguide device can include a multimode fiber. The term “waveguide device” or the like can be used herein to refer to a device that can propagate radiation by confining the radiation in a cavity and/or medium. An example of a waveguide device is an optical fiber. Another example of a waveguide device is a microwave cavity. Yet another example of a waveguide device is a strip of light-transmissive material affixed on a substrate (e.g., as can be found in photonic circuits).

According to some embodiments, detector 521a can be associated with the positive channel branch and can be configured to receive diffraction orders 517a and 519a through waveguide device 523a. Similarly, detector 521b can be associated with the negative channel branch and can be configured to receive diffraction orders 517b and 519b through waveguide device 523b. According to some embodiments, waveguide device 523a and detector 521a are configured to detect each of diffraction orders 517a and 519a spatially separate from each other. In other words, detector 521a is configured to individually measure an intensity of each of diffraction orders 517a and 519a. Similarly, waveguide device 523b and detector 521b are configured to detect each of diffraction orders 517b and 519b spatially separate from each other. In other words, detector 521b is configured to individually measure an intensity of each of diffraction orders 517b and 519b. Therefore, waveguide device 523 and detector 521 are configured to detect each of the plurality of diffraction orders spatially separate from other ones of the plurality of diffraction orders. And detector 521 is configured to individually measure an intensity of each of the plurality of diffraction orders.

According to some embodiments, intensity channel 500 is used with target 501, which can be a one-dimensional target. For example, target 501 can include a grating with segments (for example, but not limited to grating lines) in X direction or a grating with segments (for example, but not limited to grating lines) in Y direction. In some examples, target 501 can include segments (for example, but not limited to grating lines) that are diagonal or are under any other angles. In some examples, the segments of target 501 can include a checker-board stretched in one direction with respect to the other direction. In these embodiments, detector 521 is configured to individually measure the intensity of each of the plurality of diffraction orders in one direction (e.g., X direction, Y direction, etc.)

Additionally, or alternatively, intensity channel 500 can be used with target 501 that can include dual pitch marks. In these embodiments, target 501 can include segments in, for example, X and Y directions with different pitches. Intensity channel 500 can be configured to separate the diffraction orders in the X direction from the diffraction orders in the Y direction. According to some examples, intensity channel 500 can include two sets of detectors 521. A first set of detectors can measure the intensity of each of the plurality of diffraction orders in a first direction (e.g., the X direction). A second set of detectors can measure the intensity of each of the plurality of diffraction orders in a second direction (e.g., the Y direction).

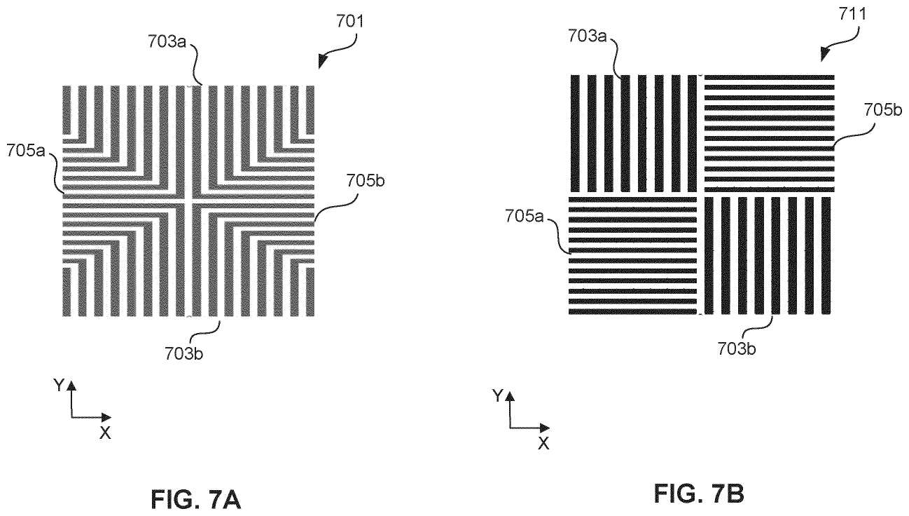

FIGS. 7A and 7B illustrate exemplary targets with different pitches, according to some embodiments. For example, FIG. 7A illustrates target 701 (e.g., an alignment target) that can be used as target 501 of FIG. 5A.

Target 701 of FIG. 7A can include segments 703a and 703b (collectively referred to as segment 703) and segments 705a and 705b (collectively referred to as segment 705). In this exemplary target, segment 703 has target lines where each target line is parallel to the Y axis. Also, segment 705 has target lines where each target line is parallel to the X axis. In this exemplary target, the pitch of segment 703 is different from the pitch of segment 705.

Target 711 of FIG. 7B can include segments 713a and 713b (collectively referred to as segment 713) and segments 715a and 715b (collectively referred to as segment 715). In this exemplary target, segment 713 has target lines where each target line is parallel to the Y axis. Also, segment 715 has target lines where each target line is parallel to the X axis. In this exemplary target, the pitch of segment 713 is different from the pitch of segment 715.

Although some examples of target 501 (or targets 701 and 711) are discussed with gratings having segments in X and Y directions, the embodiments of this disclosure are not limited to these examples and the segments of target 501 (or targets 701 and 711) can be diagonal or under any other angles. Also, the segments of target 501 (or targets 701 and 711) can include, but are not limited to, grating lines, a checker-board stretched in one direction with respect to the other direction, or the like.

By using a dual pitch target (e.g., target 701 or 711), in a pupil plane, the location of a diffraction order can have a different radial position for the first direction (e.g., the X direction) as for the second directions (e.g., the Y direction). Therefore, the diffraction order can be separated for the first direction with respect to the second direction. According to some examples, a radial numerical aperture (NA) filter can be used to separate the diffraction orders for different directions. In some examples, the pupil plane can be the pupil plane of projection system 507 and the radial NA filter can be in place of or in addition with pupil divider 511. Therefore, as discussed above, according to some embodiments, intensity channel 500 of FIG. 5A can include two sets of detectors 521. A first set of detectors can measure the intensity of each of the plurality of diffraction orders in a first direction (e.g., the X direction). A second set of detectors can measure the intensity of each of the plurality of diffraction orders in a second direction (e.g., the Y direction). Alternatively, one set of detectors can be used to first measure the intensity of each of the plurality of diffraction orders in the first direction (e.g., the X direction) and later measure the intensity of each of the plurality of diffraction orders in a second direction (e.g., the Y direction).

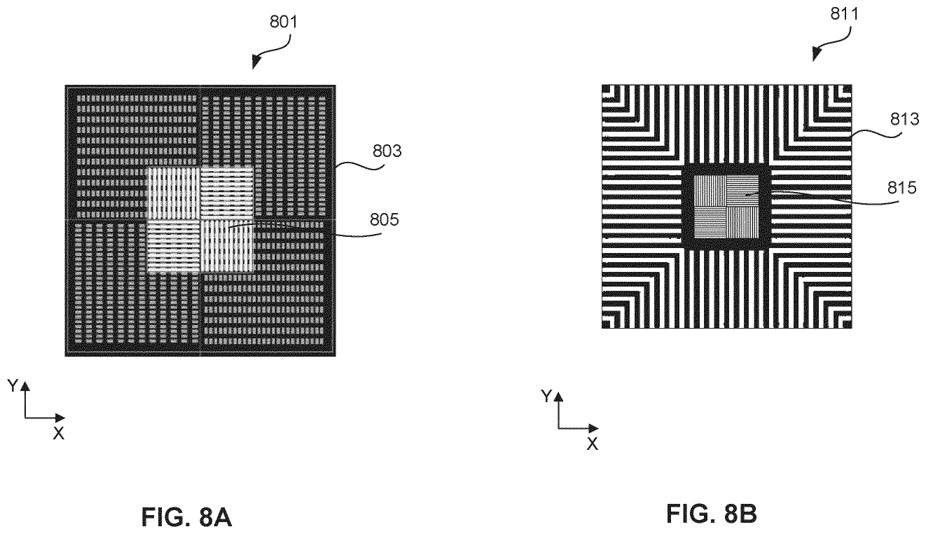

Additionally, or alternatively, intensity channel 500 can be used with target 501 that can include overlay-alignment marks. FIGS. 8A and 8B illustrate exemplary targets including overlay-alignment marks, according to some embodiments.

For example, FIG. 8A illustrates target 801 that can be used as target 501 of FIG. 5A. Target 801 can include alignment mark 803 and overlay mark 805. In some examples, overlay mark 805 can be located over (e.g., on top of) alignment mark 803. In some examples, overlay mark 805 can have smaller pitch compared to alignment mark 803. In some examples, overlay mark 805 can have subsegments that are orthogonal to the corresponding subsegment of alignment mark 803. In the exemplary target 801, overlay target 805 has four subsegments and alignment mark 803 has four subsegments. In this example, each subsegment of overlay mark 805 can be orthogonal to the corresponding subsegment of alignment mark 803 (e.g., the subsegment beneath the subsegment of overlay mark 805).

FIG. 8B illustrates target 811 that can include alignment mark 813 and overlay mark 815. In some examples, overlay mark 815 can be located over (e.g., on top of) alignment mark 813. In some examples, overly mark 815 can have smaller pitch compared to alignment mark 813. In some examples, overlay mark 815 and alignment mark 813 can be subsegmented, but the segmenting of overlay mark 815 can be different than how alignment mark 813 is segmented.

According to some embodiments, intensity channel 500 of FIG. 5A can use an NA filter to block or separate diffraction orders from the overlay mark and the alignment mark of target 501 when target 501 includes overlay-alignment marks such as target 801 or 811. For example, intensity channel 500 of FIG. 5A can include two sets of detectors 521. A first set of detectors can measure the intensity of each of the plurality of diffraction orders from the alignment mark. A second set of detectors can measure the intensity of each of the plurality of diffraction orders from the overlay mark. Alternatively, one set of detectors can be used to first measure the intensity of each of the plurality of diffraction orders from the alignment mark (e.g., by blocking diffraction orders from the overlay mark) and later measure the intensity of each of the plurality of diffraction orders from the overlay mark (e.g., by blocking diffraction orders from the alignment mark).

By separating and individually measuring the diffraction orders (e.g., diffraction orders 517 and 519), metrology system 400 (e.g., using intensity channel 500) can measure and determine, for example, intensity imbalance (e.g., difference in intensities) for different diffraction orders. For example, a processor (e.g., processor 432 of FIGS. 4A and 4B) can receive intensity measurements for diffraction orders 517 and 519. In some examples, the processor can determine a first intensity imbalance (e.g., a first intensity difference) between the measured intensities of diffraction orders 517a and 517b (e.g., the +1 and −1 diffraction orders). Additionally, or alternatively, the processor can determine a second intensity imbalance (e.g., a second intensity difference) between the measured intensities of diffraction orders 519a and 519b (e.g., the +3 and −3 diffraction orders). According to some embodiments the measured intensities and/or the determined intensity imbalances can be based on an asymmetry of target 501.

The first and/or second intensity imbalances can be used to determine a correction factor. The correction factor can be used to revise one or more characteristics of target 501 (e.g., alignment, position, overlay error, etc.) that is determined by metrology system 400. According to some embodiments, the intensity imbalances can be measured for one direction. Additionally, or alternatively, the intensity imbalances can be measured for two or more directions. For example, metrology system 400 (e.g., using intensity channel 500) can measure and determine, for example, one or more intensity imbalances for different diffraction orders in a first direction (e.g., the X direction) and can measure and determine, for example, one or more intensity imbalances for different diffraction orders in a second direction (e.g., the Y direction).

In addition to, or alternatively to, measuring the intensity, detector 521 and/or the processor can determine a distribution measurement for where each of the diffraction orders (e.g., diffraction orders 517 and 519) land on detector 521. In a non-limiting example, detector 521 can detect the energy of each one of the diffraction orders as an energy in a circle. In this example, the distribution measurement can include measuring the radius or the diameter of the circle. Additionally, or alternatively, the distribution measurement can include measuring the energy distribution of the intensity of diffraction orders within each circle. However, the embodiments of this disclosure are not limited to these examples and the distribution and the distribution measurements can include other shapes and parameters.

According to some embodiments, in addition to, or alternatively to, determining the intensity imbalance, the processor can determine a change in the distribution measurements for at least one of the diffraction orders (e.g., diffraction orders 517 and 519). In some examples, the change in the distribution measurements can be based on layer thickness variation associated with target 501. For example, the layer thickness variation associated with the target can include one or more of the layer thickness variation of the target, the layer thickness variation due to stack on top of the target, the layer thickness variation due to stack underneath the target, and the like. Additionally, other stack variations such as critical dimension (CD) variations and possibly also sensor variations (such as, but not limited to, defocus) can change the distribution measurements (and lead to alignment errors). Such effects can also be corrected with the methods and systems of this disclosure.

According to some embodiments, the processor can determine a change in the distribution measurements for at least one of the diffraction orders for one direction. Additionally, or alternatively, the processor can determine a change in the distribution measurements for at least one of the diffraction orders for two or more directions. For example, the processor can determine a change in the distribution measurements for at least one of the diffraction orders in a first direction (e.g., the X direction) and can determine a change in the distribution measurements for at least one of the diffraction orders in a second direction (e.g., the Y direction).

FIG. 5B illustrates one exemplary design for separating and individually measuring an intensity of each of a plurality of diffraction order, according to some embodiments. FIG. 5B illustrates waveguide device 523a and detector 521a, according to some embodiments. Waveguide device 523a can include input facet 525a where diffraction orders 517a and 519a enter. According to some embodiments, waveguide device 523a is arranged such that detector 521a can detect a far field radiation pattern of input facet 525a of waveguide device 523a. In other words, distance 527 between waveguide device 523a and detector 521 can be designed such that detector 521a can detect the far field radiation pattern of input facet 525a of waveguide device 523a. For example, distance 527 can be designed such that detector 521a is configured to detect a Fourier space (e.g., pupil plane) where the diffraction orders (e.g., 517 and 519) are spatially separated. For example, distance 527 can be designed such that detector 521a is configured to detect a Fourier space (e.g., pupil plane) at pupil divider 511. Pupil divider 511 can be arranged at a pupil plane of projection system 507.

Although waveguide device 523a and detector 521a are shown, the embodiments of this disclosure can also be applied to waveguide device 523b and detector 521b. Also, although one waveguide device 523a is illustrated associated with detector 521a, waveguide device 523a (and/or waveguide device 523b) can include one or more waveguide devices. In this example, each one of the one or more waveguide devices of waveguide device 523a can capture different part of the pupil plane. In this example, system 500 can include filters to perform separate filtering on each one of the one or more waveguide devices of waveguide device 523a. In other words, waveguide device 523a (and/or waveguide device 523b) can include one or more waveguide devices where each of the one or more waveguide device is arranged such that detector 521a (and/or detector 521b) detects a different part of the pupil plane of the projection system using the corresponding one of the one or more waveguide devices. In a non-limiting example, waveguide device 523a (or waveguide device 523b) can include four waveguide devices where each of the four waveguide devices can be configured to capture a quadrant of the pupil plane.

According to some embodiments, detector 521a can include a detector array. Additionally, or alternatively, detector 521 can include a two-dimensional (2D) detector or a 2D detector array. For example, detector 521 can include a camera.

FIG. 5C illustrates one exemplary energy distribution of intensity measurement on a detector, according to some embodiments. Energy distribution 530 of FIG. 5C can be associated with waveguide 523a and detector 521a of FIG. 5B.

As illustrated in the non-limiting example of FIG. 5C, energy within circle 531 corresponds to the energy distribution of the intensity of diffraction order 517a (e.g., the +1 diffraction order). In this example, energy within ring 533 corresponds to the energy distribution of the intensity of diffraction order 519a (e.g., the +3 diffraction order). In this example, the design of FIG. 5B is configured to separate the diffraction orders such that detector 521a can measure the intensity of the diffraction orders separately. According to some embodiments, the diffraction orders are separated using a region of interest (ROI). Energy within each ROI can correspond to the energy of a specific diffraction order. In this example, circle 531 can be ROI for diffraction order 517a (e.g., the +1 diffraction order) and ring 533 can ROI for diffraction order 519a (e.g., the +3 diffraction order).

Additionally, detector 521a can be configured to measure a distribution measurement for where each of the diffraction orders (e.g., diffraction orders 517 and 519) land on detector 521a. In this non-limiting example, diameter 537 can be a distribution measurement for diffraction order 517a and diameter 535 can be a distribution measurement for diffraction order 519a. In some examples, the diameter or the radius can be linked to the center-of-gravity of the diffraction order. Additionally, or alternatively, the energy distribution of the intensity within circle 531 can be a distribution measurement for diffraction order 517a and the energy distribution of the intensity within ring 533 can be a distribution measurement for diffraction order 519a. The energy distribution of the intensity can be linked to the angular distribution and spectrum of the diffraction order. However, the embodiments of this disclosure are not limited to these examples and the distribution and the distribution measurements can include other shapes and parameters.

Although some examples of FIGS. 5A-5C are discussed with respect to an intensity channel of a metrology system (e.g., metrology system 400 of FIGS. 4A and 4B), the embodiments of this disclosure are not limited to these examples. The embodiments of this disclosure can also be applied to the intensity channel of the metrology system, to the phase channel of the metrology system, or both.

In some embodiments, the exemplary energy distribution of intensity measurement on a detector of FIG. 5C and the distribution measurements discussed above can be used in the metrology system where, for example, multiple diffraction orders (such as, but not limited to, both +1 diffraction order and −1 diffraction order) are present. For example, the multiple diffraction orders (such as, but not limited to, both +1 diffraction order and −1 diffraction order) are coupled to the same waveguide device and they do not interfere with each other. In a non-limiting example, the circle and ring as shown in FIG. 5C can be present with multiple diffraction orders that can overlap. In these embodiment, similar to the embodiments discussed above, the change in the distribution measurements can be based on layer thickness variation associated with target. In other words, if multiple diffraction orders project on the same circle (e.g., circle 531) or on the same ring (e.g., ring 533) on the detector, the distribution measurements discussed in this disclosure can be used to determine and/or correct for the layer thickness variation associated with target.

The arrangement of waveguide device 523a and detector 521a as illustrated in FIG. 5B can include additional optical elements. In one example, a lens or a lens system (not shown) can be arranged between waveguide device 523a and detector 521a. In this example, output 528a of waveguide device 523a can be located at a focal point of the lens system and detector 521a can be located at a conjugate focal point of the lens system. In some examples, detector 521a can include an area detector.

In another example, a mechatronic aperture (not shown) can be arranged between waveguide device 523a and detector 521a. In this example, the mechatronic aperture (e.g., a mechanical shutter aperture) can be used to block or attenuate (e.g., partially attenuate) one or more undesired diffraction orders. In some examples, detector 521a can include a single pixel detector in conjunction with the mechatronic aperture. In a non-limiting example, the mechatronic aperture can be configured to block or attenuate (e.g., partially attenuate) the diffraction order except for diffraction order 517a (e.g., +1 diffraction order). Detector 521a (e.g., a single pixel detector) can detect and measure the intensity of diffraction order 517a. In some examples, the mechatronic aperture (not shown) can also be configured to block or attenuate one or more diffraction orders from other features not on the target (e.g., target 501). For example, in addition to, or in alternative to, blocking or attenuating diffraction orders from the target, the mechatronic aperture can block or attenuate diffraction orders from one or more features on the substrate that are not on the target but are close to the target.

In another example, detection system 505 can include additional optical elements, such as, but not limited to, spatial light modulators, digital micromirror devices, circular photodiode array, and the like. For example, one or more spatial light modulators (not shown) can be arranged between waveguide device 523a and detector 521a. Additionally, or alternatively, detector 521a can include a circular photodiode array.

FIGS. 5D and 5E show another exemplary design for separating and individually measuring an intensity of each of a plurality of diffraction orders, according to some embodiments. System 540 of FIG. 5D can be part of detection system 505 of FIG. 5A. FIG. 5D illustrates waveguide 523a and detectors 546a and 548a. According to some embodiments, detectors 546a and 548a can be part of detector 521a of FIG. 5A. Although, FIG. 5D is discussed with respect to positive diffraction orders, same or similar design can be used for negative diffraction orders (e.g., using waveguide device 523b and detector 521a of FIG. 5A).

As illustrated in FIG. 5D, one or more optical elements can be configured between waveguide device 523a and detectors 546a and 548a. According to some embodiments, the one or more optical elements can include lens (or lens system) 541, optical element 543, and lens (or lens system) 545. According to some embodiments, lens 541 is positioned at an upstream of waveguide device 523a. Optical element 543 is positioned at an upstream of lens 541. And, lens 545 is positioned at an upstream of optical element 543. In some embodiments, optical element 543 can include a tunable order splitter (or a tunable order blocker).

According to some embodiments, waveguide device 523a can include a multimode fiber. In some examples, as illustrated in FIG. 5E, waveguide device 523a can be configured to conserve angles of beam(s) (e.g., beam 551) that enter waveguide device 523a with respect to an axis (e.g., axis 553) of waveguide device 523a. In other words, the angle of a beam (e.g., beam 551 that enters waveguide device 523a) with respect to the axis (e.g., axis 553) of waveguide device 523a is the same (or substantially the same) as the angle of a beam (e.g., beam 555 that exists waveguide device 523a) with respect to the axis (e.g., axis 553) of waveguide device 523a.

In this example, diffraction orders that enter waveguide device 523a at input faucet 525a can be separated at output 528a of waveguide device 523a. In this example, diffraction order 547a (e.g., +1 diffraction order corresponding to diffraction order 517a of FIG. 5A) can pass through lens 541, optical element 543, and lens 545 and be detected by detector 546a. Similarly, diffraction order 549a (e.g., +3 diffraction order corresponding to diffraction order 519a of FIG. 5A) can pass through lens 541, optical element 543, and lens 545 and be detected by detector 548a.

In this example, detector 546a can be used to measure the intensity and/or the distribution measurement of diffraction order 547a (e.g., +1 diffraction order corresponding to diffraction order 517a of FIG. 5A). Similarly, detector 548a can be used to measure the intensity and/or the distribution measurement of diffraction order 549a (e.g., +3 diffraction order corresponding to diffraction order 519a of FIG. 5A). Although two detectors and two diffraction orders are discussed in FIG. 5D, the embodiments of this disclosure are not limited to this example and can include any number of detectors and/or diffraction orders.

System 540 of FIG. 5D can be configured to detect each of a plurality of diffraction orders spatially separate from other ones of the plurality of diffraction orders. For example, system 540 of FIG. 5D can be configured to individually measure an intensity of each of the plurality of diffraction orders and/or determine a distribution measurement for each of the plurality of diffraction orders.

According to some embodiments, optical element 543 can include a tunable order splitter configured to separate diffraction orders 547a and 549a. According to some examples, tunable order splitter can include a digital micromirror device (DMD). In addition to, or alternative to a tunable order splitter, optical element 543 can be a tunable order blocker to block diffraction orders (e.g., 547a, 549a, or other diffraction orders). In some examples, the tunable order splitter and/or tunable order blocker can include a set of rings, ring shaped wedges, etc. In one example, the tunable order splitter and/or tunable order blocker can include a set of rings, ring shaped wedges, and the like placed in a filter wheel.

According to some embodiments, instead of the tunable order splitter (e.g., a DMD), other types of spatial light modulator (SLM) can be used as optical element 543. For example, liquid-crystal based SLMs, devices with continuously tunable angles, and the like can be used as optical element 543.

Although detectors 546a and 548a are illustrated as separate detectors, detectors 546a and 548a can be combined in to one detector and/or a detector array. Additionally, or alternatively, if a tunable order blocker is used as optical element 543, the number of detectors can depend on the number of diffraction order(s) that pass through the tunable order blocker.

In some examples, if binary implementations of the tunable order splitters are used but more than two detectors (e.g., detectors 546a and 548a) are used, the tunable order splitters can be placed in a sequence (e.g. a sequence of two binary splitters can split four diffraction orders to four separate detectors).

In some embodiments, system 540 can also include one or more optional slideable fixed design order attenuation plates 561. In some embodiments, the fixed design order attenuation plates 561 can be positioned between lens 541 and optical element 543. In a non-limiting example, the fixed design order attenuation plates 561 can restrict the use of intensity channels to a slightly smaller set of colors. This color range restriction can limit the range of pure 1^{st} order, fully higher order blocked, colors to pass the detector. An example of such a slideable fixed design order attenuation plate is given in FIG. 5F. For slideable higher order attenuation plate 561 of FIG. 5F, the 2^{nd} and higher orders are attenuated, each aperture for a specific pitch. For a color range from wavelength 1 up to wavelength 2, where wavelength 2 equals twice wavelength 1, the pupil location of the 2^{nd} order of wavelength 1 corresponds to the same pupil location as the 1^{st} order of wavelength 2. So when blocking the 2^{nd} order of wavelength 1 also the 1^{st} order of wavelength 2 is blocked. Because of the physical extension of the beams in the pupil an even somewhat smaller wavelength range can pass (fully higher order blocked) towards the detector. When the pitch of an alignment mark is changed slideable higher order attenuation plate 561 is changed to another location. Although slideable higher order attenuation plate 561 is shown and discussed above, other attenuation plates can also be used. The attenuation plate(s) can be located between lens 541 and optical element 543. For example, another embodiment is to rotate a plate of apertures of different sizes into the pupil plane.

According to some embodiments, waveguide device 523a (in FIGS. 5A, 5B, and/or 5C) can include a fiber bundle (e.g., a plurality of small fibers close to each other instead of a single large-core multimode fiber). In these embodiments, the far field radiation pattern of the input (e.g., input 525a) of the waveguide device (e.g., waveguide device 523a) can be imaged to the detector(s) (e.g., detector 521a of FIG. 5B and/or detectors 546a and 548a of FIG. 5D). In these examples, a Fourier space (e.g., pupil plane) of projection system 507 is imaged to the input (e.g., input 525a) of the waveguide device (e.g., waveguide device 523a). The output (e.g., output 528a) of the waveguide device (e.g., waveguide device 523a) can be imaged on detector 521a of FIG. 5B and/or optical element 543 of FIG. 5D.

As discussed above, system 540 of FIG. 5D can be configured to individually measure an intensity of each of the plurality of diffraction orders and/or determine a distribution measurement for each of the plurality of diffraction orders. For example, optical element 543 of FIG. 5D can also be used to enable system 540 to determine distribution measurement for each of the plurality of diffraction orders.

In one embodiment, optical element 543 (e.g., the tunable order splitter) can be tuned, such that a ring of energy for +1 diffraction order ring is separated into an inner and an outer part. In this example, the inner part can be collected on a first detector and the outer part on be collected on a second detector. In some examples, the first and second detectors can be part of detector 546a of FIG. 5D. According to this embodiment, the distribution measurement for this diffraction order can be a ratio of the energy on the first and second detectors. A processor (e.g., processor 432 of FIGS. 4A and 4B) can detect a change in the ratio (e.g., a change in the distribution measurement). For example, when the layer thickness of target 501 changes, the ratio of the energy on the first and second detectors (e.g., the distribution measurement) will change. The measured change in the distribution measurement can be used in generating the correction factor discussed above.

According to some embodiments, radiation beams that exist from waveguide device 523a can include multiple colors (wavelengths). In some examples, the colors can be separated first (e.g., using a demodulation (DMUX) device such as dichroic mirrors) before the embodiments of this disclosure are applied to each color. For example, optical element 543 of FIG. 5D (e.g., the tunable order splitter) can be applied per each color. In this example, element 543 of FIG. 5D (e.g., the tunable order splitter) can be optimized for each color. In a non-limiting example, shorter wavelengths can lead to smaller angles of the beam (with respect to the optical axis of, for example, the waveguide device) and can lead to a smaller optimal order splitter.

Although some examples are discussed with respect to an intensity channel of a metrology system (e.g., metrology system 400 of FIGS. 4A and 4B), the embodiments of this disclosure are not limited to these examples. The embodiments of this disclosure can also be applied to the intensity channel of the metrology system or to the phase channel of the metrology system.

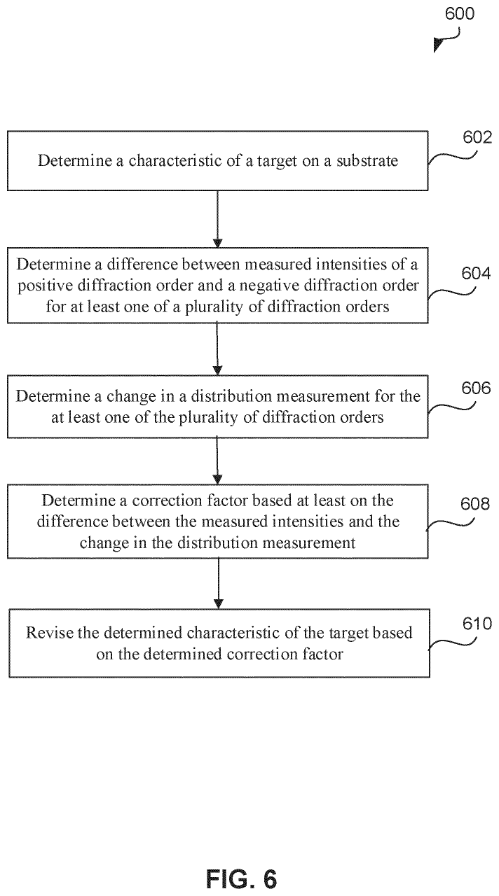

FIG. 6 illustrates an example method 600 for determining a correction factor, according to some embodiments of the disclosure. As a convenience and not a limitation, FIG. 6 may be described with regard to elements of FIGS. 4 and 5. Method 600 may represent the operation of a system (e.g., metrology system 400, system 500, and/or system 540) implementing operations for determining a correction factor and revising a determined characteristic of a target using the correction factor. Method 600 may also be performed by a processor (e.g., processor 432 of FIGS. 4A and 4B) or by a computer system. But method 600 is not limited to the specific embodiments depicted in those figures, and other systems may be used to perform the method as will be understood by those skilled in the art. It is to be appreciated that not all operations may be needed, and the operations may not be performed in the same order as shown in FIG. 6.

At 602, one or more characteristics of a target on a substrate are determined. For example, metrology system 400 of FIGS. 4A and 4B can be configured to determine one or more characteristics of alignment mark or target 418 (and/or target 501 of FIG. 5A). According to some embodiments, operation 602 can include irradiating the target with a radiation beam, collecting diffracted radiation beam(s) from the target, using an interferometer to combining the radiation beam and the diffracted radiation beam(s), detecting the combine radiation beam, and analyzing the detected combine radiation beam to determine the one or more characteristics.

The one or more characteristics can include, but are not limited to, a position of the target, an alignment of the target, an overlay error of the target, a CD associated with the target, and the like. According to some embodiments, the determined characteristic(s) of the target can be influenced by an asymmetry in the target and/or a difference in the layer thickness of the target. At 604-608, a correction factor can be determined to compensate for the asymmetry in the target and/or the difference in the layer thickness of the target. At 610, the correction factor can be applied to the determined characteristic(s) to revise the determined characteristic(s).

For example, at 604, a difference between measured intensities of a positive diffraction order and a negative diffraction order for at least one of a plurality of diffraction orders is determined. According to some embodiments, the plurality of diffraction orders are diffracted from the target and the difference between the measured intensities of the positive diffraction order and the negative diffraction order can be based on an asymmetry of the target. As discussed above, the intensity of each of the plurality of diffraction orders can be measured individually.

At 606, a change in a distribution measurement for the at least one of the plurality of diffraction orders is determined. The change in the distribution measurement can be based on a layer thickness variation associated with the target. According to some embodiments, determining the change in the distribution measurement can include determining the distribution measurement for where each of the plurality of diffraction orders land on a detector array. In some examples, the change in the distribution measurement can be determined between the distribution measurement of a positive diffraction order and the distribution measurement a negative diffraction order of the same diffraction order. Additionally, or alternatively, the change in the distribution measurement can be determined for the same diffraction order over two or more measurements.

According to some embodiments, an exemplary method to determine the change in the distribution measurement is disclosed in International Application No. WO 2021/083704 published May 6, 2021, which is incorporated by reference in its entirety. The method disclosed in International Application No. WO 2021/083704 can be used in operation 606 to model and train the determination of the change in the distribution measurement and/or the correction using the determined change. This method can be further applied to the embodiments of this disclosure where the detector(s) are located after the waveguide device(s). However, the embodiments of this disclosure are not limited to these examples, and other methods can be used to determine the change in the distribution measurement and use the determined change for generating a correction factor.

At 608, a correction factor is determined based at least on one or more of the difference between the measured intensities and the change in the distribution measurement. At 610, the determined correction factors is applied to the determined characteristic(s) of the target to revise the determined characteristic(s).

Method 600 of FIG. 6 can be used for determining a correction factor and applying the correction factor to determined characteristic(s) of a target to revise the determined characteristic(s), according to some embodiments of the disclosure. Additionally, or alternatively, systems of FIGS. 4 and 5 can be used to determine characteristic(s) of the target (e.g., to determine one or more parameters of interest of the target such as, but not limited to, an overlay). In some embodiments, a method can include collecting information about the target (e.g., alignment mark or target 418 and/or target 501 of FIG. 5A) with one or more acquisitions (e.g., per bias pad) from different parts of the pupil plane. For example, by using multiple waveguide devices as waveguide device 523a and/or using multiple waveguide devices as waveguide device 523b, information about the target can be collected using one or more acquisitions (e.g., per bias pad) from different parts of the pupil plane.

In other words, as discussed above, detector 521a (and/or detector 521b) can detect a different part of the pupil plane of the projection system using a corresponding one of the one or more waveguide devices of waveguide 523a (and/or waveguide device 523a). In some embodiments, collecting the information can include irradiating the target with a radiation beam, collecting diffracted radiation beam(s) from the target, detecting the diffracted radiation beam(s) (and/or a combine radiation beam of the radiation beam and the diffracted radiation beam(s)) at different parts of the pupil plane of the projection system using multiple waveguide devices.

This method can further include analyzing the detected radiations from different parts of the pupil plane to determine the one or more characteristics of the target. In one example, the one or more characteristics can include one or more parameters of interest based the collected information such as, but not limited to, an overlay that can be determined based on ±1 diffraction orders from ±biases on the target. According to some embodiments, the method discussed above can be performed by a processor (e.g., processor 432 of FIGS. 4A and 4B) or by a computer system.

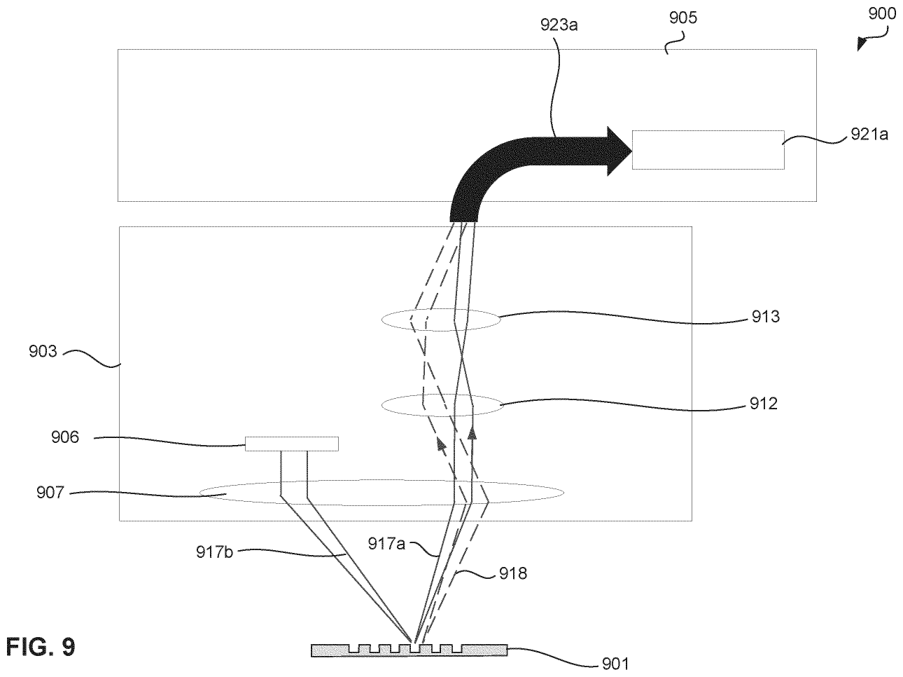

Some of the embodiments discussed above provide exemplary methods and systems to detect each of a plurality of diffraction orders spatially separate from other ones of the plurality of diffraction orders and to individually measure an intensity of each of the plurality of diffraction orders. FIG. 9 shows a schematic of an inspection apparatus configured to separate intensity measurement for a grating in a first direction from intensity measurement for a grating in a second direction, according to some embodiments. System 900 of FIG. 9 can be used with embodiments of FIGS. 5A-5H and 6-8. System 900 of FIG. 9 can be part of metrology system 400 of FIGS. 4A and 4B, as discussed above, according to some embodiments.

As discussed in more detail below, compared to intensity channel 500 of FIG. 5A, system 900 includes optical element 912 that can be located in the pupil plane of, for example, projection system 907. By using optical element 912, target 901 is not “imaged” onto waveguide device 923a, but it is in the Fourier plane with respect to waveguide device 923a. System 900 can be used with targets of FIGS. 7A. 7B, 8A, and 8B, according to some embodiments. Additionally, or alternatively, system 900 can be used with mark designs that have, for example, X grating in the center and Y grating around it (for example combined with a diagonal scan). Alternatively, target 901 can have, for example, +45 degree lines in a first mark segments, −45 degree lines in a second mark segment, and +45 degree lines in a third mark segment. In this example, system 900 can use a “straight” scan over the mark. Additionally, or alternatively, system 900 can be used with mark designs that have, for example, two directions (e.g., X and Y directions) where the mark designs can have same or substantially same pitch. For example, system 900 can be used with mark designs similar to targets 701 and 711 but having same (or substantially same) pitches for the first and second directions (e.g., the X and Y directions).

As illustrated in FIG. 9, system 900 can include target 901, optical system 903, and detection system 905. In some embodiments, target 901 can be alignment mark or target 418 of FIGS. 4A and 4B, target 501 of FIG. 5A, or targets of FIGS. 7A, 7B, 8A, and 8B. Optical system 903 can be configured to generate (or receive from a radiation source) radiation beam (not shown) to irradiate target 901. Optical system 903 can also be configured to collect diffraction orders diffracted from target 901 and guide the diffraction orders to detection system 905. According to some embodiments, optical system 903 includes one or more optical devices. For example, optical system 903 can include projection system 907. Projection system 907 can include a lens or a system of lenses, according to some embodiments. Projection system 907 can be configured to project a radiation beam (not shown) to target 901 and collect diffraction orders diffracted from target 901.

FIG. 9 illustrates +1 diffracted radiation beam 917a and −1 diffracted radiation beam 917b from a grating in a first direction (e.g., X grating) on target 901. FIG. 9 also illustrates +1 diffracted radiation beam 918 from a grating in a second direction (e.g., Y grating) on target 901. Although three diffracted radiation beams are illustrated, the embodiments of this disclosure can include any number of diffraction orders.

According to some embodiments, system 500 can include a blocker 906 configured to block the −1 diffracted radiation beams (e.g., −1 diffracted radiation beam 917b). In these examples, system 500 is discussed with respect to +1 diffracted radiation beams. However, the embodiments of this disclosure can be applied to both positive and negative diffraction orders and to first or higher diffraction orders.

Optical system 903 can also include optical elements 912 and 913 configured to guide the diffraction orders 917a and 918 to detection system 905. According to some embodiments, optical element 912 and optical element 913 can include a lens or a system of lens. According to some embodiments, and as discussed above, optical element 912 can be located in the pupil plane of, for example, projection system 907.

According to some embodiments, detection system 905 is similar to detection system 505 and can include one or more waveguide devices 923a and one or more detectors 921a. According to some embodiments, waveguide devices 923a is similar to waveguide devices 523a (or 523b) of FIG. 5A or 5D. According to some embodiments, detectors 921a are similar to detectors 521a (or 521b) of FIG. 5A and/or detectors 546a or 548a of FIG. 5D.

According to some embodiments, diffraction order 917a (e.g., +1 diffraction order) from the grating in the first direction and diffraction order 918 (e.g., +1 diffraction order) from the grating in the second direction (that is different from the first direction) are captured by waveguide device 923a. Detector 921a can be configured to receive diffraction orders 917a and 918. According to some embodiments, waveguide device 923a and detector 921a are configured to detect each of diffraction orders 917a and 918 spatially separate from each other. In other words, detector 921a is configured to individually measure an intensity of each of diffraction orders 917a and 918. Therefore, waveguide device 923a and detector 921a are configured to detect each of the plurality of diffraction orders from gratings with different directions spatially separate from other ones of the plurality of diffraction orders. And detector 921a is configured to individually measure an intensity of each of the plurality of diffraction orders. According to some embodiments, systems of FIGS. 5B and/or 5D or method 600 can be used to individually measure an intensity of each of the plurality of diffraction orders.

Additionally, system 900 is configured to determine distribution measurement for where each of the plurality of diffraction orders land on detector 921a. For example, systems of FIGS. 5B and/or 5D or method 600 can be used to determine distribution measurement for where each of the plurality of diffraction orders land on detector 921a.

According to some embodiments, and referring to FIG. 5C, circle 531 and ring 533 can also be used to show the intensity measurement and the distribution measurement for system 900. For example, with respect to FIG. 9, energy within circle 531 can correspond to the energy distribution of the intensity of diffraction order 917a (e.g., the +1 diffraction order from the grating in the first direction). In this example, energy within ring 533 can correspond to the energy distribution of the intensity of diffraction order 918 (e.g., the +1 diffraction order from the grating in the second direction).

As discussed above, method 600 for determining a difference between measured intensities, a determining change in a distribution measurement, determining a correction factor based at least on the difference between the measured intensities and the change in the distribution measurement, and revising a determined characteristic of a target based on the determined correction factor can be used with system 900 of FIG. 9. In some embodiments, when method 600 is used with system 900, determine the difference between measured intensities can include determining the difference between measured intensities of a diffraction order of a grating in a first direction and a diffraction order of a grating in a second direction different from the first direction.

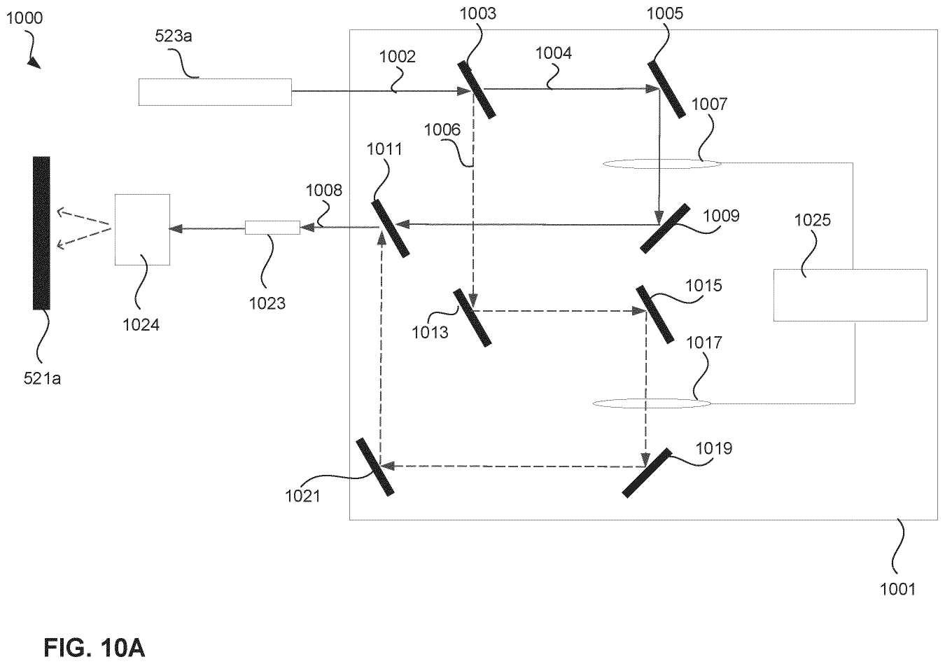

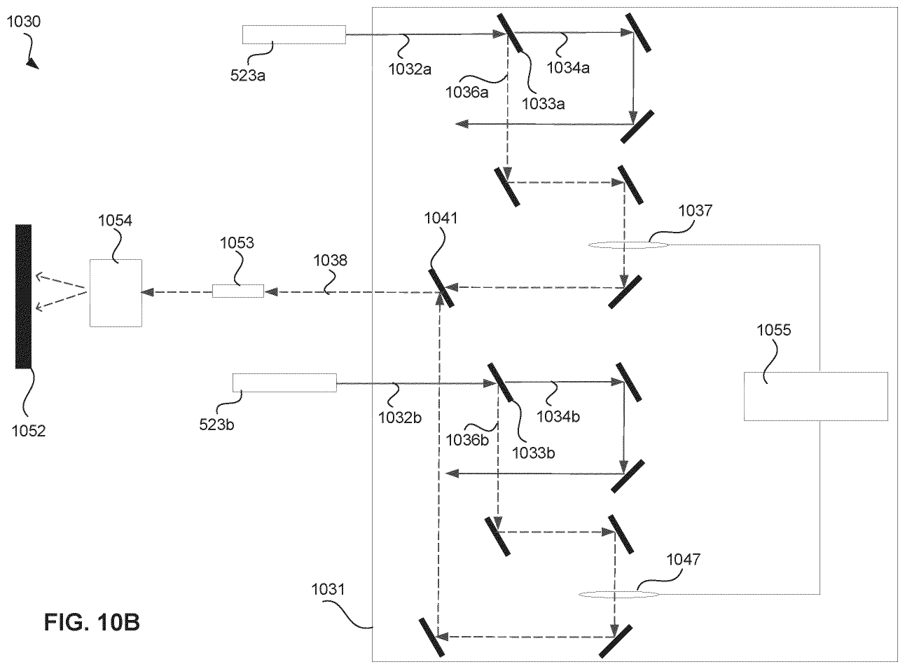

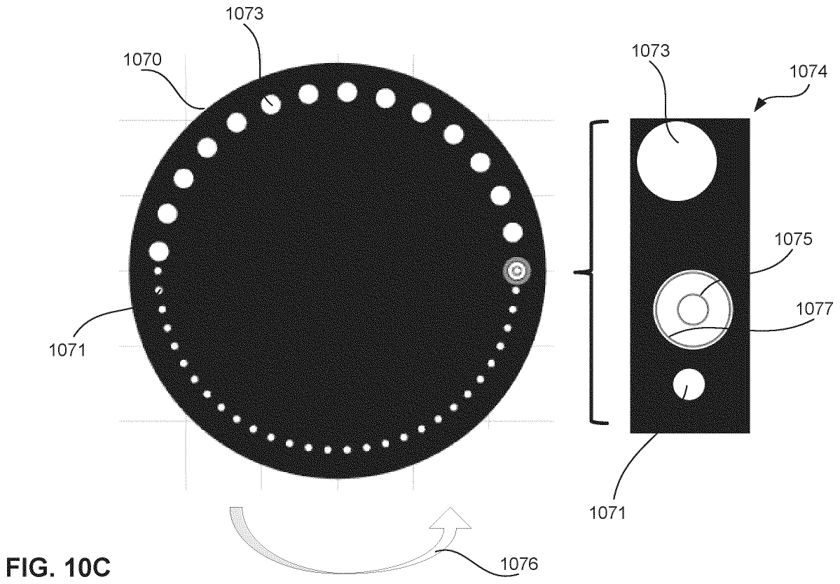

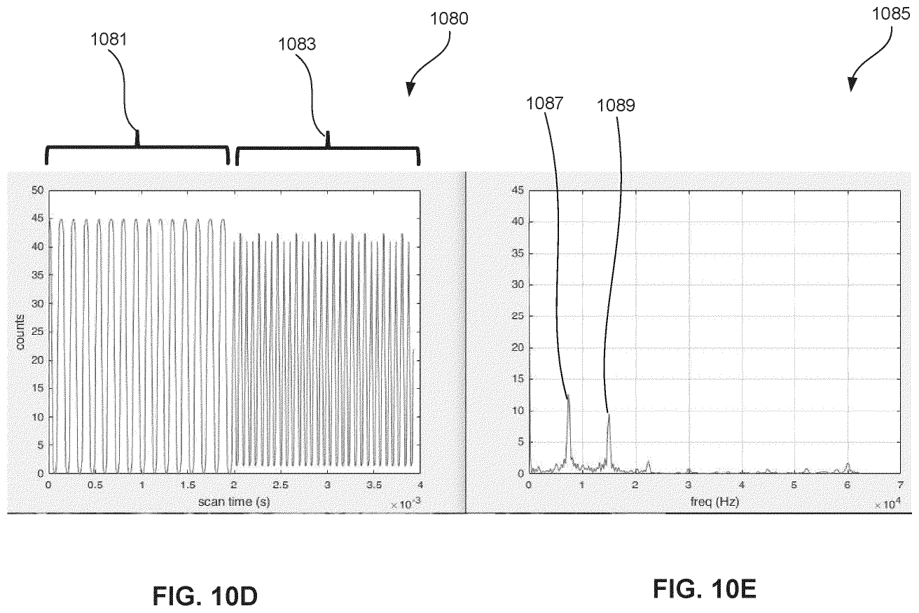

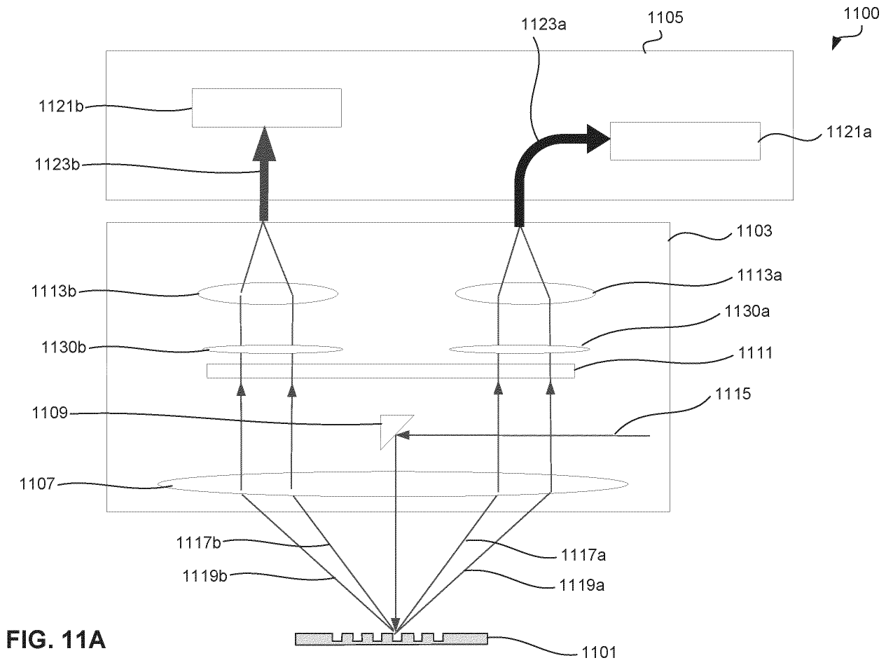

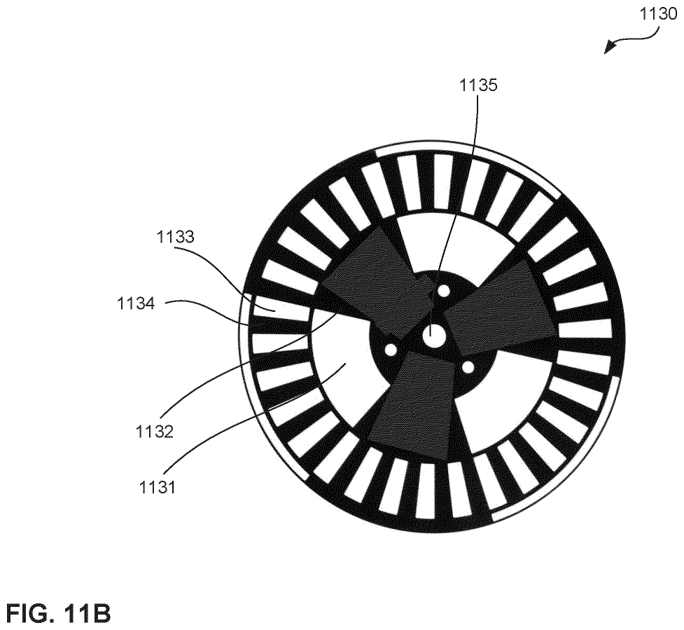

According to some embodiments, the systems and methods discussed above for detecting each of the plurality of diffraction orders spatially separate from each other and for individually measuring intensity and/or distribution measurement for each diffraction order are directed to using DC signals. As discussed in more detail below, similar systems and methods can be used for frequency discriminated signals. For example, as discussed in more detail with respect to FIGS. 10A-10E and 11A-B, one or more chopper wheels before the detector can be used to selectively allow diffraction orders to go through to provide modulation bases differentiation between the diffraction orders. In some embodiments, the one or more chopper wheels can be located within an optical system (e.g., optical system 503 of FIG. 5A). Additionally, or alternatively, the one or more chopper wheels can be located outside of the optical system (e.g., optical system 503 of FIG. 5A) and before the detector(s).

According to some embodiments, by using the frequency modulation, the signals detected by the detector(s) can be moved away from DC in the frequency domain allowing low noise detection. Additionally, or alternatively, diffraction orders can be separated, as discussed above, which can result in removal of higher diffraction orders and therefore, reducing error. In some examples, repetitive and/or in-line dark current calibration can allow lower drift. Additionally, or alternatively, inter mark gain drift can be compensated for by multiplexing positive (+) and negative (−) diffraction order optical signals onto the same detector. Multiplexing can also drive down cost by reducing number of detector board and multiplexing modules. According to some embodiments, the examples of FIGS. 10A-10E and 11A-B can be used for intensity channels and detector board for phase channels can be used for detecting intensity channel signals and therefore, reducing the number of detector boards. Also, the distribution measurement (as discussed above) can be determined using rise/fall times of detected signal.

FIG. 10A shows an exemplary design for separating and individually measuring an intensity of each of a plurality of diffraction order using chopper wheels, according to some embodiments of the disclosure. System 1000 of FIG. 10A can be part of detection system 505 of FIG. 5A. FIG. 10A illustrates waveguide 523a and detector 521a similar to the waveguide and the detector of FIG. 5A and/or FIG. 5B. Although, FIG. 10A is discussed with respect to positive diffraction orders, same or similar design can be used for negative diffraction orders (e.g., using waveguide device 523b and detector 521a of FIG. 5A).

According to some embodiments, diffraction orders collected from the target are directed to frequency discriminating for intensity signal (FDIS) system 1001 using waveguide device 523a. In some examples, FDIS system 1001 can include high pass filter 1003 configured to receive diffraction orders 1002 from waveguide device 523a. High pass filter 1003 can be configured to filter diffraction orders 1002 to two or more wavelength bands. In this example, high pass filter 1003 can split diffraction orders 1002 to diffraction orders 1004 in a first wavelength band (such as, but not limited to, about 652 nm to about 900 nm) and to diffraction orders 1006 in a second wavelength band (such as, but not limited to, about 508 nm to about 652 nm). Some examples of this disclosure are discussed with respect to two wavelength bands and exemplary wavelengths, but the embodiments of this disclosure are not limited to these examples and one or more wavelength bands and other wavelength values can be used.

According to some embodiments, chopper wheel 1007 is in the path of diffraction orders 1004 and chopper wheel 1017 is in the path of diffraction orders 1006. In other words, diffraction orders 1004 can go through chopper wheel 1007 and diffraction orders 1006 can go through chopper wheel 1017. After going through chopper wheels 1007 and 1017, diffraction orders 1004 and 1006 can be combined into diffraction orders 1008 using high pass filter 1011. According to some embodiments, FDIS system 1001 can include one or more mirrors 1003, 1005, 1009, 1013, 1015, 1019, and 1021 in order to direct diffraction orders 1004 and diffraction orders 1006 toward high pass filter 1011. After the diffraction orders from different wavelength bands are combined in diffraction orders 1008, diffraction orders 1008 are collected by waveguide device 1023 and are directed to demodulation system 1024. Diffraction orders 1008 are detected by detector 521a after demodulation system 1024.

According to some embodiments, FDIS system 1001 can include controller 1025 configured to control the operations of chopper wheel 1007 and/or chopper wheel 1017. For example, controller 1025 can control the frequency (or the frequencies) at which chopper wheel 1007 and/or chopper wheel 1017 rotate around a center of chopper wheel 1007 and/or chopper wheel 1017.

FIG. 10C illustrates an exemplary design of chopper wheel 1070, according to some embodiments. Chopper wheel 1070 can be used as chopper wheel 1007, 1017, 1037, and/or 1047 of FIGS. 10A and 10B. In this example, chopper wheel 1070 is illustrated as a circle that can rotate around the center of the circle. As illustrated in FIG. 10C, chopper wheel 1070 can include an opaque material with a plurality of openings 1071 and 1073. In this exemplary embodiment, openings 1071 can be used to allow only first diffraction orders (e.g., +1 and/or −1 diffraction orders) pass through chopper wheel 1070. Openings 1073 can be used to allow first and higher diffraction orders (e.g., +1, +3 and/or −1, −3 diffraction orders) pass through chopper wheel 1070. This is shown in the zoomed illustration 1074 where first order diffraction 1075 and higher order diffraction 1077 pass through opening 1073. According to some examples, chopper wheel 1070 can rotate around its center in direction 1076.

Continuing with the example of chopper wheel 1070, the detected signal at the detector will have two distinctive frequency components. For example, the detected signal will have a first frequency component at a first frequency and will have a second frequency component at a second frequency different from the first frequency. According to some embodiments, the first and second frequencies can depend on one or more of the number of the openings, the size (e.g., the diameter) of the openings, the design of the openings, or the frequency of rotation of chopper wheel 1070. In this example, the detected first diffraction order (e.g., +1 diffraction order) can be detected at the first frequency and the first and higher diffraction orders (e.g., +1 and +3 diffraction orders can be detected at the second frequency different from the first frequency. Therefore, using the chopper wheel in systems of FIGS. 10A-10E can result in detecting each of the plurality of diffraction orders separate from other ones of the plurality of diffraction orders at different frequencies. Additionally, or alternatively, detector 521a can detect each of the plurality of diffraction orders spatially separate from other ones of the plurality of diffraction orders.

The exemplary chopper wheel 1070 includes a first plurality of openings 1071 for the first diffraction order and a second plurality of openings 1073 for the first and the higher diffraction orders. The number of the openings, the design of the openings, the size (e.g., the diameter) of the openings, and the frequency of rotation of chopper wheel 1070 are not limited to the examples of this disclosure and can include any other designs.

FIGS. 10D and 10E illustrate exemplary intensity signal detected at time domain and frequency domain, respectively, according to some embodiments. FIG. 10D illustrates measured intensity 1080 at time domain for first diffraction order and first and higher diffraction orders. For example, FIG. 10D illustrates measured intensity 1081 for first diffraction order (e.g., +1 diffraction order) and measured intensity 1083 for first and higher diffraction orders (e.g., +1 and +3 diffraction orders). FIG. 10E illustrates measured intensity 1085 at frequency domain for first diffraction order and first and higher diffraction orders in the time domain. For example, FIG. 10E illustrates measured intensity 1087 for first diffraction order (e.g., +1 diffraction order) and measured intensity 1089 for first and higher diffraction orders (e.g., +1 and +3 diffraction orders) in the frequency domain. In one example a Fast Fourier Transform (FFT) can be used to convert measured intensity in time domain to measured intensity in frequency domain.

In addition to measuring the intensity of different diffraction orders separately from each other, systems of FIGS. 10A-10B can be used to determine a distribution measurement (and/or change the distribution measurement) for each diffraction order. As discussed above, in some examples, the change in the distribution measurements can be based on layer thickness variation associated with target 501. For example, the layer thickness variation associated with the target can include one or more of the layer thickness variation of the target, the layer thickness variation due to stack on top of the target, the layer thickness variation due to stack underneath the target, and the like. Additionally, other stack variations such as critical dimension (CD) variations and possibly also sensor variations (such as, but not limited to, defocus) can change the distribution measurements (and lead to alignment errors). According to some embodiments, by measuring the rising time and/or the fall time of detected signals from the chopper wheels, systems of FIGS. 10A-10E can determine the distribution measurement (and/or change the distribution measurement) for each diffraction order. For example, by measuring the rising time and/or the fall time of measured intensity 1081 for first diffraction order (e.g., +1 diffraction order) of FIG. 10D, the distribution measurement (and/or change the distribution measurement) for the first diffraction order can be determined. Similarly, by measuring the rising time and/or the fall time of measured intensity 1083 for first and higher diffraction orders (e.g., +1 and +3 diffraction orders), the distribution measurement (and/or change the distribution measurement) for the higher diffraction order (e.g., +3 diffraction order) can be determined.

In the exemplary embodiment of FIG. 10A, FDIS system 1001 is used for the positive channel branch including positive diffraction orders (e.g., +1. +3, . . . diffraction orders). According to some embodiments, additional FDIS system can be used for the negative channel branch including negative diffraction orders (e.g., −1, −3, . . . diffraction orders). Additionally, or alternatively, a FDIS system can be used for combining positive and negative diffraction orders.

FIG. 10B shows another exemplary design for separating and individually measuring an intensity of each of a plurality of diffraction order using chopper wheels, according to some embodiments of the disclosure. System 1030 of FIG. 10A can be part of detection system 505 of FIG. 5A. FIG. 10D illustrates waveguides 523a and 523b similar to the waveguides of FIG. 5A and/or FIG. 5B. System 1030 can include detector 1052. According to some examples, detector 1052 can be similar to detector 521a or 521b of FIG. 5A and/or FIG. 5B.

According to some embodiments, system 1030 of FIG. 10B can be similar to system 1010 of FIG. 10A. Additionally, system 1030 can be configured to combine the positive channel branch including positive diffraction orders (e.g., +1, +3, . . . diffraction orders) with the negative channel branch including negative diffraction orders (e.g., −1, −3, . . . diffraction orders).

According to some embodiments, positive diffraction orders collected from the target are directed to frequency discriminating for intensity signal (FDIS) system 1031 using waveguide device 523a. Similarly, negative diffraction orders collected from the target are directed to frequency discriminating for intensity signal (FDIS) system 1031 using waveguide device 523b.

In some examples, FDIS system 1031 can include high pass filter 1033a configured to receive diffraction orders 1032a (positive diffraction orders) from waveguide device 523a. High pass filter 1033a can be configured to filter diffraction orders 1032a to two or more wavelength bands. In this example, high pass filter 1033a can split diffraction orders 1032a to diffraction orders 1034a in a first wavelength band (such as, but not limited to, about 652 nm to about 900 nm) and to diffraction orders 1036a in a second wavelength band (such as, but not limited to, about 508 nm to about 652 nm). Some examples of this disclosure are discussed with respect to two wavelength bands and exemplary wavelengths, but the embodiments of this disclosure are not limited to these examples and one or more wavelength bands and other wavelength values can be used.

Additionally, FDIS system 1031 can include high pass filter 1033b configured to receive diffraction orders 1032b (negative diffraction orders) from waveguide device 523b. High pass filter 1033b can be configured to filter diffraction orders 1032b to two or more wavelength bands. In this example, high pass filter 1033b can split diffraction orders 1032b to diffraction orders 1034b in a first wavelength band (such as, but not limited to, about 652 nm to about 900 nm) and to diffraction orders 1036b in a second wavelength band (such as, but not limited to, about 508 nm to about 652 nm). Some examples of this disclosure are discussed with respect to two wavelength bands and exemplary wavelengths, but the embodiments of this disclosure are not limited to these examples and one or more wavelength bands and other wavelength values can be used.

According to some embodiments, diffraction orders 1036a can go through chopper wheel 1037 and diffraction orders 1036b can go through chopper wheel 1047. After going through chopper wheels 1037 and 1047, diffraction orders 1036a and 1036b can be combined into diffraction orders 1038 using high pass filter 1041. According to some embodiments, FDIS system 1031 can include one or more mirrors in order to direct diffraction orders 1036a and 1036b (and/or diffraction orders 1034a and 1034b) toward high pass filter 1041. After the diffraction orders from different wavelength bands are combined in diffraction orders 1038, diffraction orders 1038 are collected by waveguide device 1053 and are directed to demodulation system 1054. Diffraction orders 1038 are detected by detector 1052 after demodulation system 1054.

Although FIG. 10B illustrates that negative and positive diffraction orders of the second wavelength band are combined to diffraction orders 1038, negative and positive diffraction orders of the first wavelength band can also be combined (not shown). In some examples, negative and positive diffraction orders of the first wavelength band and the second wavelength band can be combined into diffraction orders 1038. In this example, one detector can be used to detect both positive and negative diffraction orders instead of, for example, using two detectors (one for positive diffraction orders and one for negative diffraction orders).

According to some embodiments, FDIS system 1031 can include controller 1055 configured to control the operations of chopper wheel 1037 and/or chopper wheel 1047. For example, controller 1055 can control the frequency (or the frequencies) at which chopper wheel 1037 and/or chopper wheel 1047 rotate around their respective center. In some examples, controller 1055 can control both chopper wheel 1037 and chopper wheel 1047 simultaneously (or substantially simultaneously). In some examples, controller 1055 can control chopper wheel 1037 separately from chopper wheel 1047.

According to some embodiments, the detected signal on detector 1052 can have different frequency—for example, a first frequency for +1 diffraction order, a second frequency for −1 diffraction order, a third frequency for +1 and higher positive diffraction orders, and a fourth frequency for −1 and higher negative diffraction orders.

FIG. 11A shows another exemplary design for separating and individually measuring an intensity of each of a plurality of diffraction order using chopper wheels within an optical system, according to some embodiments of the disclosure. System 1100 of FIG. 11A is similar to intensity channel 500 of FIG. 5. System 1100 can include target 1101, optical system 1103, and detection system 1105. Optical system 1103 can be configured to generate (or receive from a radiation source) radiation beam 1115 to irradiate target 1101. Optical system 1103 can also be configured to collect diffraction orders diffracted from target 1101 and guide the diffraction orders to detection system 1105. According to some embodiments, optical system 1103 includes one or more optical devices. For example, optical system 1103 can include optical element 1109 configured to receive radiation beam 1115 and change direction of radiation beam 1115 to irradiate target 1101.

Optical system 1103 can also include projection system 1107. Projection system 1107 can include a lens or a system of lenses, according to some embodiments. Projection system 1107 can be configured to project radiation beam 1115 to target 1101 and collect diffraction orders diffracted from target 1101. FIG. 11A illustrates +1 diffracted radiation beam 1117a, −1 diffracted radiation beam 1117b, +3 diffracted radiation beam 1119a, and −3 diffracted radiation beam 1119b. Although four diffracted radiation beams are illustrated, the embodiments of this disclosure can include any number of diffraction orders. According to some embodiments, optical system 1103 can also include pupil divider 1111. Pupil divider 1111 can be configured to separate positive (+) and negative (−) diffraction order channels. These element can be similar to and/or operate in a similar manner as their corresponding elements in FIG. 5A.

According to some embodiments, optical system 1103 can include one or more chopper wheels. For example, as illustrated in FIG. 11A, optical system 1103 can include a first chopper wheel 1130a in the positive channel branch and a second chopper wheel 1130b in the negative channel branch. In another example (not shown), optical system 1103 can include one chopper wheel for both positive and negative channel branches. The embodiments of this disclosure are not limited to these examples, and optical system 1103 can include any number of chopper wheels.

By using chopper wheels 1130a and/or 1130b, the signal associated with the first diffraction order (positive or negative) and the higher diffraction orders (positive or negative) that are detected at detectors 1121a and/or 1121b will have different frequencies.

FIG. 11B illustrates an exemplary design of chopper wheel 1130 to be used within the optical system, according to some embodiments. In the exemplary design of FIG. 11B, chopper wheel 1130 can include an inner ring including one or more opaque sections 1132 and one or more openings 1131. Chopper wheel 1130 can also include an outer ring including one or more opaque sections 1134 and one or more openings 1133. In this exemplary design, the inner ring of chopper wheel 1130 can be used for first diffraction order (e.g., +1 and/or −1 diffraction order) and the outer ring of chopper wheel 1130 can be used for higher diffraction orders. Chopper wheel 1130 can be configured to rotate around its center 1135.

The embodiments of this disclosure are not limited to this exemplary design and chopper wheel 1130 can include other designs (e.g., one or more rings, different number of opaque sections/openings, different shapes for opaque sections/openings, different patterns, and the like).

As discussed above, method 600 for determining a difference between measured intensities, a determining change in a distribution measurement, determining a correction factor based at least on the difference between the measured intensities and the change in the distribution measurement, and revising a determined characteristic of a target based on the determined correction factor can be used with systems of FIGS. 10A-10E and 11A-11B.

The embodiments may further be described using the following clauses:

1. A metrology system, comprising:
a projection system configured to receive a plurality of diffraction orders diffracted from a target on a substrate;
a detector array; and
a waveguide device configured to transmit the plurality of diffraction orders between the projection system and the detector array,
wherein the detector array is configured to detect each of the plurality of diffraction orders spatially separate from other ones of the plurality of diffraction orders.

2. The metrology system of clause 1, wherein the detector array is configured to individually measure an intensity of each of the plurality of diffraction orders.

3. The metrology system of clause 2, wherein the detector array is configured to determine a distribution measurement for where each of the plurality of diffraction orders land on the detector array.

4. The metrology system of clause 3, further comprising:
a processor configured to:
determine a characteristic of the target;
determine a correction factor based at least on one of:
   a difference between the measured intensities of a positive diffraction order and a negative diffraction order for at least one of the plurality of diffraction orders, and
   a change in the distribution measurement for the at least one of the plurality of diffraction orders; and
revise the determined characteristic of the target based on the determined correction factor.

5. The metrology system of clause 4, wherein the difference between the measured intensities of the positive diffraction order and the negative diffraction order is based on an asymmetry of the target.

6. The metrology system of clause 4, wherein the change in the distribution measurement is based on a layer thickness variation associated with the target.

7. The metrology system of clause 1, wherein:
the detector array is configured to determine a distribution measurement for where each of the plurality of diffraction orders land on the detector array, and
the metrology system further comprises a processor configured to determine a change in the distribution measurement for the at least one of the plurality of diffraction order, the change in the distribution measurement being based on a layer thickness variation associated with the target.

8. The metrology system of clause 1, wherein the waveguide device is arranged such that the detector array is configured to detect a far field radiation pattern of an input to the waveguide device.

9. The metrology system of clause 8, further comprising:
a lens system,
wherein an output of the waveguide device is located at a focal point of the lens system, and
wherein the detector array is located at a conjugate focal point of the lens system.

10. The metrology system of clause 8, wherein a distance between the waveguide device and the detector array is arranged such that the detector array detects at a pupil plane of the projection system.

11. The metrology system of clause 8, further comprising:
a mechatronic aperture configured to block or attenuate one or more of the plurality of diffraction orders, wherein the detector array comprises a single pixel detector.

12. The metrology system of clause 1, further comprising:
a first lens system positioned at an upstream of the waveguide device;
an optical element positioned at an upstream of the first lens system; and
a second lens system positioned at an upstream of the optical element.

13. The metrology system of clause 12, wherein:
the detector array comprises a first detector configured to detect a first one of the plurality of diffraction orders and a second detector configured to detect a second one of the plurality of diffraction orders, and
the optical element comprises at least one of a tunable order splitter, a tunable order blocker, or a spatial light modulator.

14. The metrology system of clause 1, wherein the waveguide device comprises a multimode fiber.

15. The metrology system of clause 1, wherein the waveguide device comprises a fiber bundle.

16. The metrology system of clause 1, wherein the waveguide device comprises one or more waveguide devices, each of the one or more waveguide device arranged such that the detector array detects a different part of a pupil plane of the projection system using the corresponding one of the one or more waveguide devices.

17. The metrology system of clause 1, wherein the target comprises dual pitch marks comprising a first segment having a first pitch and a second segment having a second pitch different from the first pitch.

18. The metrology system of clause 17, wherein the detector array is further configured to detect each of the plurality of diffraction orders spatially separate from other ones of the plurality of diffraction orders in the first direction separate from the second direction.

19. A metrology system, comprising:
a detector array; and
one or more waveguide devices configured to receive a plurality of diffraction orders diffracted from a target on a substrate and to transmit the plurality of diffraction orders to the detector array,
wherein the one or more waveguide devices are arranged such that detector array detects a far field radiation pattern of an input to the one or more waveguide devices in order to detect each of the plurality of diffraction orders spatially separate from other ones of the plurality of diffraction orders.

20. The metrology system of clause 19, wherein the detector array is configured to:
individually measure an intensity of each of the plurality of diffraction orders; and
determine a distribution measurement for where each of the plurality of diffraction orders land on the two-dimensional detector.

21. The metrology system of clause 20, further comprising:
a processor configured to:
   determine a characteristic of the target;
   determine a correction factor based at least on one of:
      a difference between the measured intensities of a positive diffraction order and a negative diffraction order for at least one of the plurality of diffraction orders, wherein the difference between the measured intensities of the positive diffraction order and the negative diffraction order is based on an asymmetry of the target, and
      a change in the distribution measurement for the at least one of the plurality of diffraction orders, wherein the change in the distribution measurement is based on a layer thickness variation associated with the target; and
   revise the determined characteristic of the target based on the determined correction factor.

22. The metrology system of clause 19, further comprising:
a lens system, wherein an output of the one or more waveguide devices is located at a focal point of the lens system and wherein the detector array is located at a conjugate focal point of the lens system.

23. The metrology system of clause 19, further comprising:
a mechatronic aperture configured to block or attenuate one or more of the plurality of diffraction orders, wherein the detector array comprises a single pixel detector.

24. A method, comprising:
determining a characteristic of a target on a substrate;
determining a difference between measured intensities of a positive diffraction order and a negative diffraction order for at least one of a plurality of diffraction orders,
wherein the plurality of diffraction orders are diffracted from the target, and
wherein the difference between the measured intensities of the positive diffraction order and the negative diffraction order is based on an asymmetry of the target,
determining a change in a distribution measurement for the at least one of the plurality of diffraction orders, wherein the change in the distribution measurement is based on a layer thickness variation associated with the target;
determining a correction factor based at least on the difference between the measured intensities and the change in the distribution measurement; and
revising the determined characteristic of the target based on the determined correction factor.

25. A metrology system, comprising:
a projection system configured to receive a plurality of diffraction orders diffracted from a target on a substrate, wherein:
   the target comprises a first grating in a first direction and a second grating in a second direction, and
   the plurality of diffraction orders comprises a first diffraction order from the first grating and a second diffraction order from the second grating;
a detector array; and
a waveguide device configured to transmit the plurality of diffraction orders between the projection system and the detector array,
wherein the detector array is configured to detect the first diffraction order spatially separate from the second diffraction order.

26. The metrology system of clause 25, further comprising a lens located at a pupil plane of the projection system.

27. A metrology system, comprising:
a projection system configured to receive a plurality of diffraction orders diffracted from a target on a substrate;
a detector;
a waveguide device configured to transmit the plurality of diffraction orders between the projection system and the detector; and
a chopper wheel configured to rotate around a center of the chopper wheel such that the detector is configured to detect each of the plurality of diffraction orders at a frequency different from frequencies of other ones of the plurality of diffraction orders.

28. The metrology system of clause 27, wherein the chopper wheel is located between the waveguide device and the detector.

29. The metrology system of clause 28, further comprising:
a first high pass filter configured to filter the plurality of diffraction orders to a first set of diffraction orders having a first wavelength band and a second set of diffraction orders having a second wavelength band, wherein the chopper wheel is located in a path of the first set of diffraction orders;
a second chopper wheel located in a path of the second set of diffraction orders; and
a second high pass filter configured to combine the first set of diffraction orders and the second set of diffraction orders before the detector.

30. The metrology system of clause 28, wherein:
the plurality of diffraction orders comprise positive diffraction orders,
the chopper wheel is located in a path of the positive diffraction orders, and
the metrology system further including:
   a second waveguide device configured to transmit negative diffraction orders between the projection system and the detector;
   a second chopper wheel located in a path of the negative diffraction orders; and
   a high pass filter configured to combine the positive diffraction orders and the negative diffraction orders after the chopper wheel and the second chopper wheel and before the detector.

31. The metrology system of clause 28, wherein the chopper wheel comprises a first set of openings corresponding to a first diffraction order of the plurality of diffraction orders and a second set of opening corresponding to a higher diffraction order of the plurality of diffraction orders.

32. The metrology system of clause 27, wherein the chopper wheel is located before the waveguide device and the detector.

33. The metrology system of clause 32, wherein:
the plurality of diffraction orders comprise positive diffraction orders,
the chopper wheel is located in a path of the positive diffraction orders, and
the metrology system further including:
   a second chopper wheel located before a second waveguide device and a second detector and in a path of negative diffraction orders.

34. The metrology system of clause 32, wherein the chopper wheel comprises a first ring comprising a first set of openings corresponding to a first diffraction order of the plurality of diffraction orders and a second ring comprising a second set of opening corresponding to a higher diffraction order of the plurality of diffraction orders.

35. The metrology system of clause 27, wherein the detector is configured to individually measure an intensity of each of the plurality of diffraction orders.

36. The metrology system of clause 35, wherein the detector is configured to determine a distribution measurement for each of the plurality of diffraction orders.

37. The metrology system of clause 36, further comprising:
a processor configured to:
determine a characteristic of the target;
determine a correction factor based at least on one of:
   a difference between the measured intensities of a positive diffraction order and a negative diffraction order for at least one of the plurality of diffraction orders, and
   a change in the distribution measurement for the at least one of the plurality of diffraction orders; and
revise the determined characteristic of the target based on the determined correction factor.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as synonymous with the more general terms “substrate” or “target portion”, respectively. The substrate referred to herein can be processed, before or after exposure, in for example a track unit (a tool that typically applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

Although specific reference may have been made above to the use of embodiments of the present disclosure in the context of optical lithography, it will be appreciated that the present disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The terms “radiation,” “beam.” “light.” “illumination.” or the like as used herein may encompass all types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some embodiments, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

The term “substrate” as used herein describes a material onto which material layers are added. In some embodiments, the substrate itself can be patterned and materials added on top of it may also be patterned, or may remain without patterning.

Although specific reference can be made in this text to the use of the apparatus and/or system according to the present disclosure in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle.” “wafer,” or “die” in this text should be considered as being replaced by the more general terms “mask.” “substrate.” and “target portion,” respectively.

While specific embodiments of the disclosure have been described above, it will be appreciated that embodiments of the present disclosure may be practiced otherwise than as described. The descriptions are intended to be illustrative, not limiting. Thus it will be apparent to one skilled in the art that modifications may be made to the disclosure as described without departing from the scope of the claims set out below.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the protected subject matter should not be limited by any of the above-described exemplary embodiments, but should be defined only in accordance with the following claims and their equivalents.

1. A metrology system, comprising:
a projection system configured to receive a plurality of diffraction orders diffracted from a target on a substrate;
a detector array; and
a waveguide device configured to transmit the plurality of diffraction orders between the projection system and the detector array,
wherein the detector array is configured to detect each of the plurality of diffraction orders spatially separate from other ones of the plurality of diffraction orders.

2. The metrology system of claim 1, wherein the detector array is configured to individually measure an intensity of each of the plurality of diffraction orders.

3. The metrology system of claim 2, wherein the detector array is configured to determine a distribution measurement for where each of the plurality of diffraction orders land on the detector array.

4. The metrology system of claim 3, further comprising:
a processor configured to:
determine a characteristic of the target;
determine a correction factor based at least on one of:
a difference between the measured intensities of a positive diffraction order and a negative diffraction order for at least one of the plurality of diffraction orders, and
a change in the distribution measurement for the at least one of the plurality of diffraction orders; and
revise the determined characteristic of the target based on the determined correction factor.

5. The metrology system of claim 4, wherein the difference between the measured intensities of the positive diffraction order and the negative diffraction order is based on an asymmetry of the target.

6. The metrology system of claim 4, wherein the change in the distribution measurement is based on a layer thickness variation associated with the target.

7. The metrology system of claim 1, wherein:
the detector array is configured to determine a distribution measurement for where each of the plurality of diffraction orders land on the detector array, and
the metrology system further comprises a processor configured to determine a change in the distribution measurement for the at least one of the plurality of diffraction order, the change in the distribution measurement being based on a layer thickness variation associated with the target.

8. The metrology system of claim 1, wherein the waveguide device is arranged such that the detector array is configured to detect a far field radiation pattern of an input to the waveguide device.

9. The metrology system of claim 8, further comprising:
a lens system,
wherein an output of the waveguide device is located at a focal point of the lens system, and
wherein the detector array is located at a conjugate focal point of the lens system.

10. The metrology system of claim 8, wherein a distance between the waveguide device and the detector array is arranged such that the detector array detects at a pupil plane of the projection system.

11. The metrology system of claim 8, further comprising:
a mechatronic aperture configured to block or attenuate one or more of the plurality of diffraction orders, wherein the detector array comprises a single pixel detector.

12. The metrology system of claim 1, further comprising:
a first lens system positioned at an upstream of the waveguide device;
an optical element positioned at an upstream of the first lens system; and
a second lens system positioned at an upstream of the optical element.

13. The metrology system of claim 12, wherein:
the detector array comprises a first detector configured to detect a first one of the plurality of diffraction orders and a second detector configured to detect a second one of the plurality of diffraction orders, and
the optical element comprises at least one of a tunable order splitter, a tunable order blocker, or a spatial light modulator.

14. The metrology system of claim 1, wherein the waveguide device comprises a multimode fiber.

15. The metrology system of claim 1, wherein the waveguide device comprises a fiber bundle.

16. The metrology system of claim 1, wherein the waveguide device comprises one or more waveguide devices, each of the one or more waveguide device arranged such that the detector array detects a different part of a pupil plane of the projection system using the corresponding one of the one or more waveguide devices.

17. The metrology system of claim 1, wherein the target comprises dual pitch marks comprising a first segment having a first pitch and a second segment having a second pitch different from the first pitch.

18. The metrology system of claim 17, wherein the detector array is further configured to detect each of the plurality of diffraction orders spatially separate from other ones of the plurality of diffraction orders in the first direction separate from the second direction.
